(19) United States
(12) Patent Application Publication
(10) Pub. No.: US 2026/0033061 A1
(43) Pub. Date: Jan. 29, 2026

(54) DISPLAY PANEL AND METHOD OF MANUFACTURING THE SAME

(71) Applicant: LG Display Co., Ltd., Seoul (KR)

(72) Inventors: Ye Ji KIM, Paju-si (KR); Eun Min JO, Paju-si (KR)

(73) Assignee: LG Display Co., Ltd., Seoul (KR)

(21) Appl. No.: 19/255,654

(22) Filed: Jun. 30, 2025

(30) Foreign Application Priority Data
Jul. 25, 2024 (KR) 10-2024-0098881

(51) Int. Cl. H10H 29/37; H10H 29/02; H10H 29/34

(52) U.S. Cl. CPC H10H 29/37; H10H 29/02; H10H 29/34

(57) ABSTRACT

A display panel and a method of manufacturing the same are discussed. The display panel can include a first light-emitting element disposed on a first bank, a second light-emitting element disposed on a second bank, and a third light-emitting element disposed on a third bank. The first light-emitting element, the second light-emitting element, and the third light-emitting element are configured to emit light of different wavelengths. Further, at least one of the first bank, the second bank, and the third bank has a size different from a size of any of the other banks.

### CROSS-REFERENCE TO RELATED APPLICATION

This application claims priority to Korean Patent Application No. 10-2024-0098881, filed in the Republic of Korea on Jul. 25, 2024, the disclosure of which is hereby expressly incorporated by reference in its entirety into the present application.

### BACKGROUND

### Technical Field

The present specification relates to a display panel and a method of manufacturing the same.

### Discussion of the Related Art

Display devices are being applied to various electronic devices such as TVs, mobile phones, laptop computers, and tablets.

Display devices include organic light-emitting display (OLED) devices, which are self-emissive, liquid crystal display (LCD) devices, which require a separate light source, and the like.

In recent years, display devices including light-emitting diodes (LEDs) have been attracting attention as next-generation display devices. Since LEDs are formed of inorganic materials rather than organic materials, the display devices including LEDs have a fast lighting speed and high luminous efficiency, and can display high-brightness images compared to liquid crystal display devices or organic light-emitting display devices.

In transferring the inorganic light-emitting elements of a display device, a multi-place transfer method can be used, in which the light-emitting elements are picked up from a wafer once and transferred multiple times.

In the multi-place transfer method, technical issues such as a decrease in reliability can occur due to collisions between the picked-up elements and banks during transfer, and thus, a solution to address this limitation is needed.

### SUMMARY OF THE DISCLOSURE

The present disclosure is directed to providing a display panel in which process reliability is improved, and a method of manufacturing the same.

The present disclosure is also directed to providing a display panel in which process economy is improved by preventing damage to light-emitting elements during processing, and a method of manufacturing the same.

Objectives according to embodiments of the present disclosure are not limited to the above-described objectives, and other objectives that are not described herein will be apparently understood by those skilled in the art from the following description.

According to an aspect of the present invention, there is provided a display panel including a first light-emitting element disposed on a first bank, a second light-emitting element disposed on a second bank, and a third light-emitting element disposed on a third bank, wherein the first light-emitting element, the second light-emitting element, and the third light-emitting element emit light of different wavelengths, and at least one of the first bank, the second bank, and the third bank has a size different from a size of any of the other banks.

Specific details according to various examples of the present disclosure other than the means for solving the problems described above are included in the description and drawings below.

### BRIEF DESCRIPTION OF THE DRAWINGS

The above and other objects, features, and advantages of the present invention will become more apparent to those of ordinary skill in the art by describing example embodiments thereof in detail with reference to the accompanying drawings, in which:

FIG. 1 is an exploded perspective view of a display device according to an embodiment of the present disclosure;

FIG. 2 is a plan view illustrating the display device according to the embodiment of the present disclosure;

FIG. 3 is an enlarged view illustrating the display device according to the embodiment of the present disclosure;

FIG. 4 is a diagram illustrating a circuit structure according to an embodiment of the present disclosure;

FIG. 5 is a plan view of a wafer according to an embodiment of the present disclosure;

FIGS. 6A to 6C are process views illustrating a method of picking up light-emitting elements according to the embodiment of the present disclosure;

FIG. 7 is a plan view illustrating a display device according to an embodiment of the present disclosure;

FIGS. 8A to 8C are plan views according to a transfer process of light-emitting elements;

FIG. 9 is a plan view illustrating the display device according to the embodiment of the present disclosure;

FIGS. 10 to 12 are cross-sectional views illustrating a process of transferring light-emitting elements of the display device according to the present disclosure;

FIG. 13 is a cross-sectional view of the display device according to the embodiment of the present disclosure, taken along line I-I′ of FIG. 3;

FIG. 14 is a cross-sectional view illustrating the display device according to the embodiment of the present disclosure;

FIG. 15 is a view illustrating a device to which the display devices according to the embodiments of the present disclosure are applied;

FIG. 16 is a view illustrating a device to which the display devices according to the embodiments of the present disclosure are applied;

FIG. 17 is a view illustrating a device to which the display devices according to the embodiments of the present disclosure are applied; and

FIG. 18 is a view illustrating a device to which the display devices according to the embodiments of the present disclosure are applied.

### DETAILED DESCRIPTION OF THE EMBODIMENTS

Advantages and features of the present disclosure and a method of achieving the same should become clear with embodiments described in detail below with reference to the accompanying drawings. However, the present disclosure is not limited to the embodiments described below and can be implemented in various different forms. The embodiments are merely provided to allow those skilled in the art to completely understand the scope of the present disclosure.

The shapes, dimensions, ratios, angles, numbers, and the like disclosed in the drawings for describing the embodiments of the present disclosure are merely illustrative and are not limited to matters shown in the present disclosure. Like reference numerals refer to like elements throughout the disclosure. Further, in describing the present disclosure, detailed descriptions of well-known technologies will be omitted when it is determined that they can unnecessarily obscure the gist of the present disclosure. Terms such as “including,” “having,” and “composed of” used herein are intended to allow other elements to be added unless the terms are used with the term “only.” Any references to the singular can include the plural unless expressly stated otherwise.

Components are interpreted as including an ordinary error range even if no such margin is explicitly stated.

In the case of a description of a positional relationship, for example, in the case in which a positional relationship between two portions is described with the terms “on,” “above,” “under,” “next to,” or the like, one or more portions can be interposed therebetween unless the term, for example, “right”, “directly”, or “near” is used in the expression.

For the description of a temporal relationship, when a temporal relationship is described as “after,” “subsequently to,” “next,” “before,” and the like, a non-consecutive case can be included unless the term “immediately” or “directly” is used in the expression.

Although the terms “first,” “second,” and the like can be used herein to describe various components, the components are not limited by the terms. These terms are used only to distinguish one component from another. Therefore, a first component described below can be a second component within the technical scope of the present disclosure.

Terms such as first, second, A, B, (a), (b), or the like can be used herein when describing components of the present disclosure. Such terms are used only to distinguish a component from another component, but do not limit the nature, sequence, order, number, or the like of components.

It is to be understood that when a component is described as being “connected,” “coupled,” “linked,” or “attached” to another component, the component can be directly connected, coupled, linked, or attached to the other component, but, unless specifically stated otherwise, still another component can be interposed between the two components so that they are indirectly connected, coupled, linked, or attached.

It is also to be understood that when a component or layer is described as “being in contact with” or “overlapping” another component or layer, the component or layer can be in direct contact with or directly overlapping the other component or layer, but, unless specifically stated otherwise, still another component or layer can be interposed between these two components or layers so that they are in indirect contact with or indirectly overlapping each other.

The term “at least one” should be understood as including any and all combinations of one or more of the associated listed components. For example, the meaning of “at least one of a first component, a second component, and a third component” denotes any combination of two or more of the first component, the second component, and the third component as well as any of the first component, the second component, or the third component.

The terms “first direction,” “second direction,” “third direction,” “X-axis direction,” “Y-axis direction,” and “Z-axis direction” should not be interpreted as referring only to geometrical relationships that are perpendicular to each other, but can indicate a broader range of directions within the functional scope of the configuration described in the present disclosure. Further, the term “can” fully encompasses all the meanings and coverages of the term “may” and vice versa.

Features of various embodiments of the present disclosure can be partially or fully coupled or combined with each other, and technically, various types of interconnection and driving are possible. The embodiments of the present disclosure can be implemented independently of each other, or can be implemented together in a related relationship.

Hereinafter, various embodiments of the present disclosure will be described in detail with reference to the accompanying drawings. All the components of each display device/apparatus according to all embodiments of the present disclosure are operatively coupled and configured.

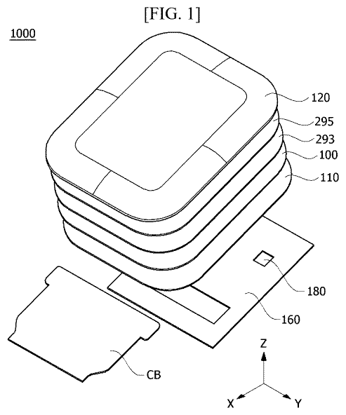

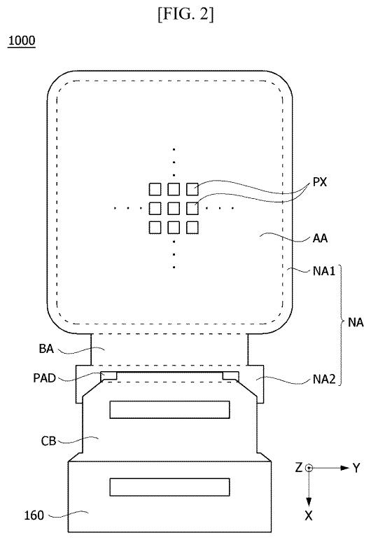

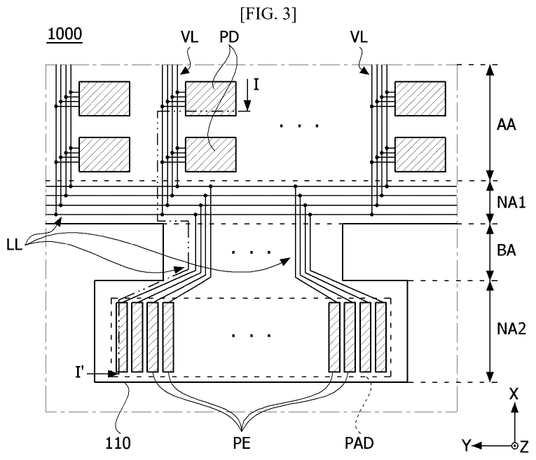

FIG. 1 is an exploded perspective view illustrating a display device according to an embodiment of the present disclosure. FIG. 2 is a plan view illustrating the display device according to the embodiment of the present disclosure. FIG. 3 is an enlarged view illustrating the display device according to the embodiment of the present disclosure.

Referring to FIGS. 1 to 3, a display device 1000 according to an embodiment of the present disclosure can include a display panel 100, a polarizing layer 293, a second adhesive layer 295, a cover member 120, a support substrate 110, a flexible circuit board CB, and a printed circuit board 160.

For example, the display device 1000 can include a substrate 110. The substrate 110 can be a member that supports other components of the display device 1000. The substrate 110 can be formed of an insulating material. For example, the substrate 110 can be formed of glass, resin, or the like. In addition, the substrate 110 can be formed of a material that has flexibility. For example, the substrate 110 can be formed of a plastic material having flexibility, such as polyimide (PI). However, the embodiments of the present disclosure are not limited thereto.

The display panel 100 can implement information, videos, and/or images provided to a user. For example, the display panel 100 can include a display area AA (or active area) and a non-display area NA (or non-active area). For example, the substrate 110 can include the display area AA and the non-display area NA. The display area AA and the non-display area NA are not limited to the substrate 110 but can be provided throughout the entire display device 1000.

The display area AA can be an area in which an image is displayed. The display area AA can include a plurality of pixels PX. Each of the plurality of pixels PX can be composed of a plurality of sub-pixels. A plurality of light-emitting elements can be disposed in each of the plurality of sub-pixels. The plurality of light-emitting elements can be configured differently depending on the type of the display device 1000. For example, when the display device 1000 is an inorganic light-emitting display device, the light-emitting element can be a light-emitting diode (LED), a micro light-emitting diode (micro LED), or a mini light-emitting diode (mini LED), but the embodiments of the present disclosure are not limited thereto.

The non-display area NA can be an area in which an image is not displayed. Various lines, circuits, and the like for driving the plurality of pixels PX of the display area AA can be disposed in the non-display area NA. For example, in the non-display area NA, various lines and driving circuits can be mounted, and a pad part PAD to which an integrated circuit, a printed circuit, or the like is connected can be disposed, but the embodiments of the present disclosure are not limited thereto.

For example, the driving circuits can be data driving circuits and/or gate driving circuits, but the embodiments of the present disclosure are not limited thereto. Lines through which control signals for controlling the driving circuits are supplied can be disposed on the display panel 100. For example, the control signals can include various timing signals such as clock signals, input data enable signals, and synchronization signals, but the embodiments of the present disclosure are not limited thereto. The control signals can be received through the pad part PAD. For example, link lines LL for transmitting signals can be disposed in the non-display area NA. For example, driving components such as the flexible circuit board CB and the printed circuit board 160 can be connected to the pad part PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA can be an area extending from at least one of a plurality of sides of the first non-display area NA1, and can be a bendable area. The second non-display area NA2 can be an area extending from the bending area BA, and the pad part PAD can be disposed therein. For example, the bending area BA can be in a bent state, and the remaining area of the substrate 110, excluding the bending area BA, can be in a flat state. In this case, as the bending area BA is bent, the second non-display area NA2 can be located on a rear surface of the display area AA. However, the embodiments of the present disclosure are not limited thereto.

The display area AA of the substrate 110 or the display device 1000 can be configured in various shapes depending on the design of the display device 1000. For example, the display area AA can be configured in a rectangular shape with four rounded corners, but the embodiments of the present disclosure are not limited thereto. For another example, the display area AA can be configured in a rectangular shape with four right-angled corners, a circular shape, or the like, but the embodiments of the present disclosure are not limited thereto.

According to the present disclosure, a width of the second non-display area NA2, in which a plurality of pad electrodes PE are disposed, can be greater than a width of the bending area BA, in which only the plurality of link lines LL are disposed. In addition, a width of the display area AA in which the plurality of sub-pixels are disposed can be greater than the width of the bending area BA in which only the plurality of link lines LL are disposed. In the drawings, the width of the bending area BA is illustrated as being less than that of each of the other areas of the substrate 110, but the shape of the substrate 110 including the bending area BA is an example, and the embodiments of the present disclosure are not limited thereto.

A plurality of pixel driving circuits PD can be disposed in the display area AA. The plurality of pixel driving circuits PD can be circuits for driving the light-emitting elements of the plurality of sub-pixels. Each of the plurality of pixel driving circuits PD includes a plurality of transistors including driving transistors, a storage capacitor, and the like, and the pixel driving circuits PD can supply control signals, power, and driving current to the light-emitting elements of the plurality of sub-pixels, thereby controlling the light-emission operations of the plurality of light-emitting elements. For example, the pixel driving circuit PD can include power lines and signal lines for controlling an on/off state and/or a light-emission time of the light-emitting element. For example, the plurality of pixel driving circuits PD can be driving drivers fabricated using a metal-oxide-silicon field-effect transistor (MOSFET) manufacturing process on a semiconductor substrate, but the embodiments of the present disclosure are not limited thereto. The driving drivers include the plurality of pixel driving circuits PD, and can drive the plurality of sub-pixels.

The flexible circuit board CB and the printed circuit board 160 can be disposed below the display panel 100. The flexible circuit board CB and the printed circuit board 160 can be disposed at at least one side edge of the display panel 100, but the embodiments of the present disclosure are not limited thereto. One side of the flexible circuit board CB can be attached to the display panel 100, and the other side thereof can be attached to the printed circuit board 160, but the embodiments of the present disclosure are not limited thereto. The flexible circuit board CB can be a flexible film, but the embodiments of the present disclosure are not limited thereto.

The pad part PAD including the plurality of pad electrodes PE can be disposed in the second non-display area NA2. The driving components including one or more flexible circuit boards (or flexible films) CB and the printed circuit board 160 can be attached or bonded to the pad part PAD. The plurality of pad electrodes PE of the pad part PAD are electrically connected to one or more flexible circuit boards (or flexible films) CB and can transmit various signals (or power) output from the printed circuit board 160 and the flexible circuit boards (or flexible films) CB to the plurality of pixel driving circuits PD in the display area AA.

The flexible circuit board (or flexible film) CB can be a film in which various components are disposed on a base film having flexibility. For example, a driving integrated circuit (IC) such as a gate driver IC or a data driver IC can be disposed on the flexible circuit board (or flexible film) CB, but the embodiments of the present disclosure are not limited thereto. The driving IC can be a component that processes data and driving signals for displaying images. The driving IC can be disposed using methods such as chip on glass (COG), chip on film (COF), or tape carrier package (TCP) depending on a mounting method, but the embodiments of the present disclosure are not limited thereto. The flexible circuit board (or flexible film) CB can be attached or bonded onto the plurality of pad electrodes PE through a conductive adhesive layer, but the embodiments of the present disclosure are not limited thereto.

The printed circuit board 160 can be a component that is electrically connected to one or more flexible circuit boards (or flexible films) and supplies signals to the driving IC. The printed circuit board 160 can be disposed on one side of the flexible circuit board (or flexible film) CB, and can be electrically connected to the flexible circuit board (or flexible film) CB. Various components for supplying various signals to the driving IC can be disposed on the printed circuit board 160. For example, various components such as a timing controller, a power supply part, a memory, or a processor can be disposed on the printed circuit board 160. For example, the printed circuit board 160 can include a power management integrated circuit (PMIC), but the embodiments of the present disclosure are not limited thereto.

The printed circuit board 160 can include at least one hole 180, but the embodiments of the present disclosure are not limited thereto. An internal component configured to detect ambient light or temperature, which can be provided to a plurality of sensors, can be disposed in an area corresponding to at least one hole 180. For example, the internal component can include an ambient light sensor (ALS), a temperature sensor, or the like, but the embodiments of the present disclosure are not limited thereto. For example, the hole 180 can be a through hole or the like, but the embodiments of the present disclosure are not limited thereto.

The polarizing layer 293 can be disposed on the display panel 100. The polarizing layer 293 can prevent or reduce the light generated from an external light source from entering the display panel 100 and affecting the light-emitting elements or the like.

The cover member 120 can be disposed on the polarizing layer 293. The cover member 120 can be a member for protecting the display panel 100. The second adhesive layer 295 can be disposed between the polarizing layer 293 and the cover member 120. The cover member 120 can be attached to the display panel 100 by the second adhesive layer 295. The second adhesive layer 295 can include an optically clear adhesive (OCA), an optically clear resin (OCR), a pressure-sensitive adhesive (PSA), or the like, but the embodiments of the present disclosure are not limited thereto.

The support substrate 110 can be disposed between the display panel 100 and the printed circuit board 160. The support substrate 110 can reinforce the rigidity of the display panel 100. The support substrate 110 can be a back plate, but the embodiments of the present disclosure are not limited thereto.

In the non-display area NA, the plurality of link lines LL can be disposed. The plurality of link lines LL can be lines that transmit various signals supplied from one or more flexible circuit boards (or flexible films) CB and the printed circuit board 160 to the display area AA. The plurality of link lines LL can extend from the plurality of pad electrodes PE in the second non-display area NA2 toward the bending area BA and the first non-display area NA1 and can be electrically connected to a plurality of driving lines VL in the display area AA. The plurality of pixel driving circuits PD can be driven by receiving signals from one or more flexible circuit boards (or flexible films) CB and the printed circuit board 160 through the driving lines VL in the display area AA and the link lines LL in the non-display area NA.

For example, the plurality of driving lines VL, along with the plurality of link lines LL, can serve as lines for transmitting signals output from the flexible circuit board (or flexible film) CB and the printed circuit board 160 to the plurality of pixel driving circuits PD. The plurality of driving lines VL can be disposed in the display area AA and electrically connected to the plurality of pixel driving circuits PD, respectively. The plurality of driving lines VL can extend from the display area AA toward the non-display area NA to be electrically connected to the plurality of link lines LL. Accordingly, the signals output from the flexible circuit board (or flexible film) CB and the printed circuit board 160 can be transmitted to each of the plurality of pixel driving circuits PD through the plurality of link lines LL and the plurality of driving lines VL.

As the bending area BA is bent, some of the plurality of link lines LL can also be bent. Stress can be concentrated on a portion of the bent link lines LL, and as a result, cracks can occur in the link lines LL. Accordingly, the plurality of link lines LL can be formed of a conductive material with excellent flexibility to reduce cracks during the bending of the bending area BA. For example, the plurality of link lines LL can be formed of a conductive material with excellent flexibility such as gold (Au), silver (Ag), or aluminum (Al), but the embodiments of the present disclosure are not limited thereto. In addition, the plurality of link lines LL can be formed of one of various conductive materials used in the display area AA. For example, the plurality of link lines LL can be formed of molybdenum (Mo), chromium (Cr), titanium (Ti), nickel (Ni), neodymium (Nd), copper (Cu), an alloy of silver (Ag) and magnesium (Mg), or alloys thereof, but the embodiments of the present disclosure are not limited thereto. The plurality of link lines LL can be configured in a multilayer structure including various conductive materials. For example, the plurality of link lines LL can be configured in a triple-layer structure of titanium (Ti)/aluminum (Al)/titanium (Ti), but the embodiments of the present disclosure are not limited thereto.

The plurality of link lines LL can be configured in various shapes to reduce stress. At least some of the plurality of link lines LL disposed in the bending area BA can extend in the same direction as an extension direction of the bending area BA, or extend in a direction different from the extension direction of the bending area BA to reduce stress. For example, when the bending area BA extends in one direction from the first non-display area NA1 toward the second non-display area NA2, at least some of the link lines LL disposed in the bending area BA can extend in a direction oblique to the one direction. For another example, at least some of the plurality of link lines LL can be configured in various pattern shapes. For example, at least some of the plurality of link lines LL disposed in the bending area BA can have a conductive pattern repetitively disposed in at least one shape among a diamond shape, a rhombus shape, a trapezoidal wave shape, a triangular wave shape, a sawtooth wave shape, a sine wave shape, a circular shape, and an omega (Ω) shape, but the embodiments of the present disclosure are not limited thereto. Accordingly, to minimize the stress concentrated on the plurality of link lines LL and the resulting cracks, the plurality of link lines LL can be formed in various shapes including the above-described shapes, but the embodiments of the present disclosure are not limited thereto.

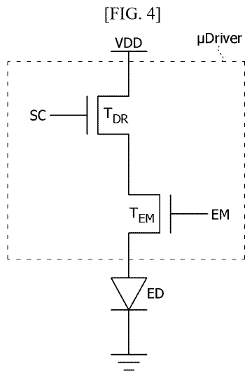

FIG. 4 is a diagram illustrating a circuit structure according to an embodiment of the present disclosure.

Referring to FIG. 4, an example is illustrated in which one light-emitting element ED is connected to a micro driver μDriver, but the present disclosure is not limited thereto. For example, eight light-emitting elements ED can be connected to one micro driver μDriver. For another example, 16 light-emitting elements ED can be connected to one micro driver μDriver, or 32 light-emitting elements ED or 64 light-emitting elements ED can be simultaneously connected to one micro driver μDriver. The light-emitting element ED can be a micro light-emitting element (μLED).

One micro driver μDriver can include a driving transistor T_{DR} and a light-emitting transistor T_{EM}, but the embodiments of the present disclosure are not limited thereto.

For example, the driving transistor T_{DR} has a first electrode to which a high-potential power supply voltage VDD can be applied, a second electrode to which a first electrode of the light-emitting transistor T_{EM} can be connected, and a gate electrode to which a scan signal SC can be applied. The scan signal SC applied to the gate electrode of the driving transistor T_{DR} can be direct current (DC) power, and a fixed reference voltage Vref can be applied for each frame, but the embodiments of the present disclosure are not limited thereto.

The light-emitting transistor T_{EM} has the first electrode to which the second electrode of the driving transistor T_{DR} can be connected, a second electrode to which the light-emitting element ED can be connected, and a gate electrode to which a light-emission signal EM can be applied. The light-emission signal EM applied to the gate electrode of the light-emitting transistor T_{EM} can be a pulse width modulation (PWM) signal that varies for each frame, but the embodiments of the present disclosure are not limited thereto.

A first electrode of the light-emitting element ED can be connected to the second electrode of the light-emitting transistor T_{EM}, and a second electrode of the light-emitting element ED can be connected to the ground. For example, the first electrode of the light-emitting element ED can be an anode, and the second electrode of the light-emitting element ED can be a cathode, but the embodiments of the present disclosure are not limited thereto.

The driving transistor T_{DR} and the light-emitting transistor T_{EM} can each be an n-type transistor or a p-type transistor.

In the micro driver μDriver, the driving transistor T_{DR} can be turned on by the scan signal SC applied from a timing controller (T-CON), and the light-emitting transistor T_{EM} can be turned on by the light-emission signal EM. As a result, a driving current can be applied to the light-emitting element ED via the driving transistor T_{DR} and the light-emitting transistor T_{EM} by the high-potential power supply voltage VDD applied to the first electrode of the driving transistor T_{DR}, thereby enabling the light-emitting element ED to emit light.

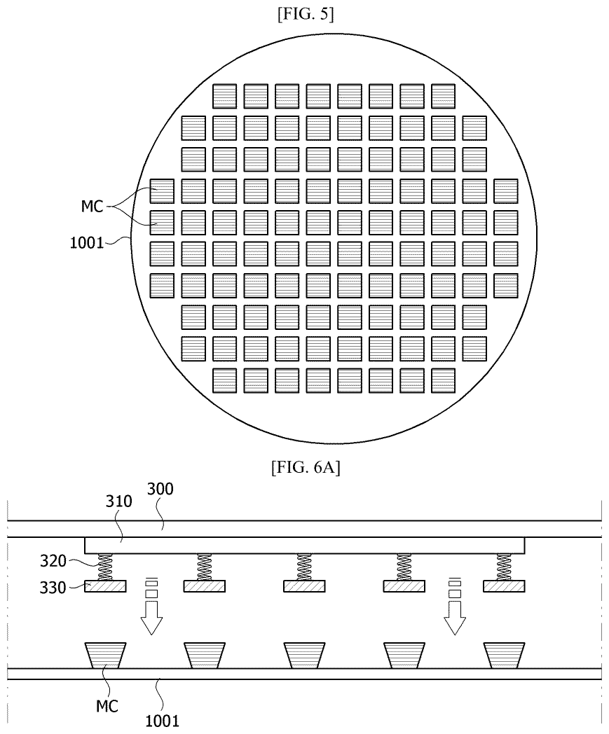

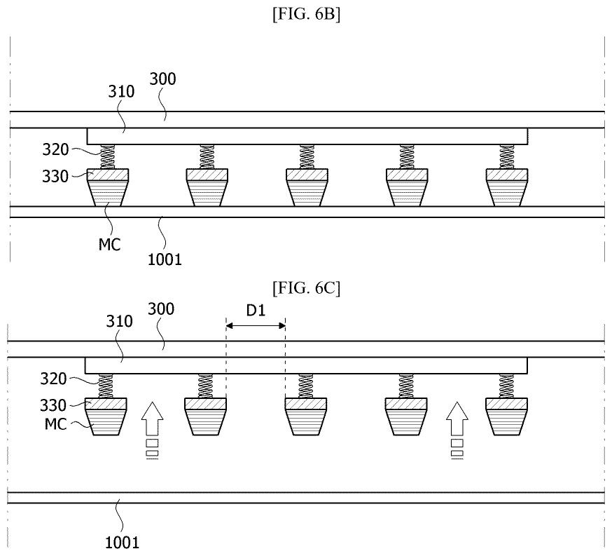

FIG. 5 is a plan view of a wafer according to an embodiment of the present disclosure. FIGS. 6A to 6C are process views illustrating a method of picking up light-emitting elements according to the embodiment of the present disclosure.

Referring to FIGS. 5 to 6C, elements MC disposed on a wafer 1001 can be inorganic light-emitting elements. For example, the inorganic light-emitting elements can be used as the light-emitting elements ED. A multi-place (MP) process can be used for the light-emitting elements ED. In the multi-place (MP) process, a plurality of elements MC of the same color are simultaneously picked up from the wafer 1001 by adhering or suctioning the inorganic light-emitting elements onto pickup heads 330 disposed on a transfer substrate 300, and only a portion of the picked-up elements are transferred to predetermined banks BNK.

A light-emitting element transfer apparatus can include the transfer substrate 300, a stamp 310 disposed below the transfer substrate 300, the pickup heads 330 configured to pick up the elements MC and disposed below the stamp 310, and elastic members 320 each connecting the pickup head 330 and the stamp 310. The pickup heads 330 can pick up the elements MC from the wafer 1001 using an adhesive layer and electrostatic force, or the like.

For example, when the multi-place (MP) process is used to transfer the light-emitting elements ED, a plurality of first light-emitting elements, which emit light in a first wavelength band among a plurality of elements MC, can be simultaneously picked up by being attached onto pickup heads 330.

Subsequently, a portion of the first light-emitting elements ED can be separated from the corresponding pickup heads 330 and transferred onto a substrate 110, and after moving the pickup heads, another portion of the first light-emitting elements ED can be separated from the corresponding pickup heads 330 and transferred onto the substrate 110, and this process can be repeated N times (where N is an integer greater than or equal to 2).

The MP process has an advantage in that the number of times of picking up the elements MC during transfer is reduced, thereby increasing a transfer speed.

When the elements MC are picked up onto the pickup heads 330 using electrostatic force, the stamp 310 can apply a voltage to the pickup heads 330. The elements MC can also be picked up onto the pickup heads 330 by utilizing van der Waals forces at the interface between the pickup heads 330 and the elements MC. In addition, the pickup heads 330 can be coated with an adhesive material on lower portions thereof to allow the elements MC to adhere upon contact, but the embodiments of the present disclosure are not limited thereto.

The pickup heads 330 can pick up the elements MC while being spaced apart from each other by a predetermined spacing D1. For example, when the elements MC to be picked up are inorganic light-emitting elements ED, the spacing D1 between the pickup heads 330 can be approximately 30 to 40 μm.

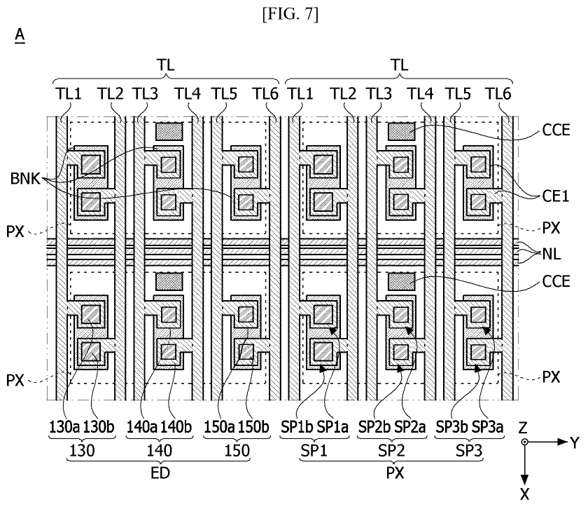

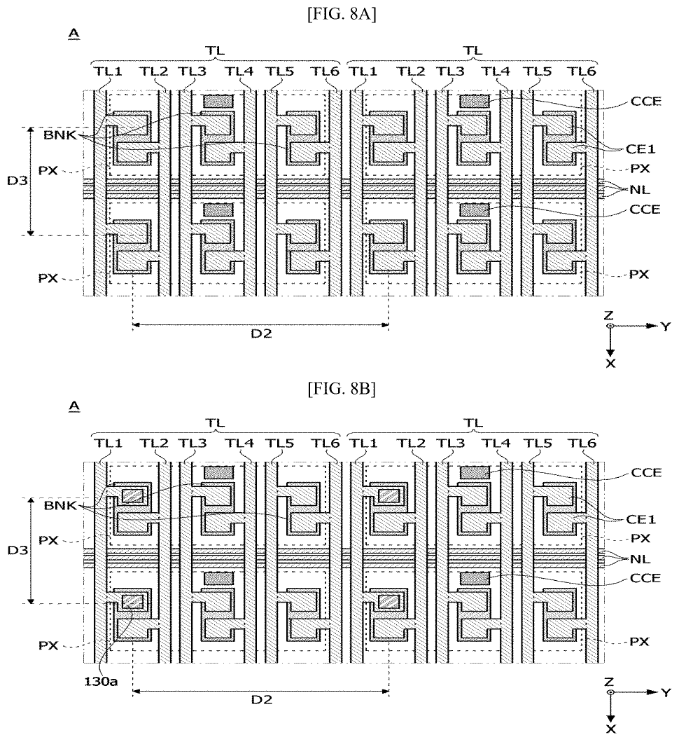

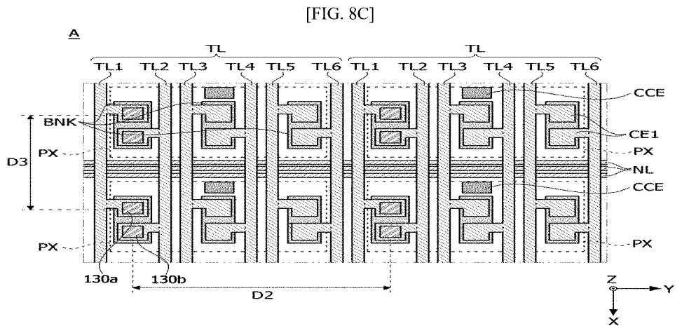

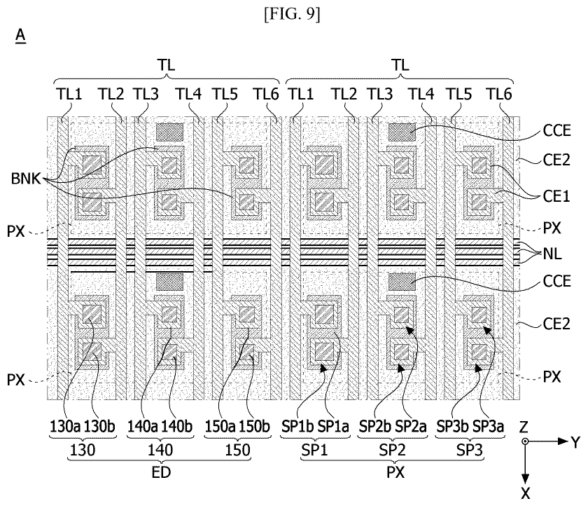

FIG. 7 is a plan view illustrating a display device according to an embodiment of the present disclosure. FIGS. 8A to 8C are plan views according to a transfer process of light-emitting elements. FIG. 9 is a plan view illustrating the display device according to the embodiment of the present disclosure.

Referring to FIGS. 7 to 8C, only a plurality of signal lines TL, a plurality of communication lines NL, a plurality of first electrodes CE1, a plurality of banks BNK, and a plurality of light-emitting elements ED are illustrated, but the embodiments of the present disclosure are not limited thereto. FIG. 9 is an enlarged plan view of the display area of FIG. 7, in which a plurality of second electrodes CE2 are additionally disposed.

Referring to FIG. 7, a plurality of pixels PX, each composed of a plurality of sub-pixels, can be disposed in a display area AA. Each of the plurality of sub-pixels can include a light-emitting element ED and can emit light independently. The plurality of sub-pixels can be disposed in a matrix form forming a plurality of rows and a plurality of columns, but the embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2, and the third sub-pixel SP3 can be a red sub-pixel, another one thereof can be a green sub-pixel, and the remaining one thereof can be a blue sub-pixel. The types of the plurality of sub-pixels are examples, and the embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can be composed of a 1-1 sub-pixel SP1a and a 1-2 sub-pixel SP1b. The pair of second sub-pixels SP2 can be composed of a 2-1 sub-pixel SP2a and a 2-2 sub-pixel SP2b. The pair of third sub-pixels SP3 can be composed of a 3-1 sub-pixel SP3a and a 3-2 sub-pixel SP3b. For example, one pixel PX can include the 1-1 sub-pixel SP1a and the 1-2 sub-pixel SP1b, the 2-1 sub-pixel SP2a and the 2-2 sub-pixel SP2b, and the 3-1 sub-pixel SP3a and the 3-2 sub-pixel SP3b, but the embodiments of the present disclosure are not limited thereto.

The plurality of sub-pixels constituting one pixel PX can be arranged in various ways. For example, in one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. The number and arrangement of the plurality of sub-pixels constituting one pixel PX are examples, and the embodiments of the present disclosure are not limited thereto.

A plurality of signal lines TL can be disposed in areas between the plurality of sub-pixels. The plurality of signal lines TL can extend in a column direction between the plurality of sub-pixels. The plurality of signal lines TL can be lines that transmit an anode voltage output from the pixel driving circuit PD to the plurality of sub-pixels. For example, the plurality of signal lines TL can be electrically connected to the plurality of pixel driving circuits PD and the first electrodes CE1 of the plurality of sub-pixels. The anode voltage output from the pixel driving circuit PD can be transmitted to the first electrodes CE1 of the plurality of sub-pixels through the plurality of signal lines TL. For example, the first electrode CE1 can be an electrode that is electrically connected to an anode 134 of the light-emitting element ED. Thus, the anode voltage transmitted through the signal line TL can be transmitted to the anode 134 of the light-emitting element ED through the first electrode CE1.

Accordingly, the structure of the display device 1000 can be simplified by using the pixel driving circuit PD, in which a plurality of pixel circuits are integrated, instead of forming a plurality of transistors and a storage capacitor in each of the plurality of sub-pixels. In addition, as the circuits disposed in each of the plurality of sub-pixels are integrated into one pixel driving circuit PD, high-efficiency and low-power operation can be enabled. The integration of circuits respectively disposed in the plurality of sub-pixels into one pixel driving circuit PD means that the pixel driving circuit PD includes a plurality of pixel circuits capable of driving the plurality of light-emitting elements ED. The plurality of light-emitting elements ED can be driven by one pixel driving circuit PD in which a plurality of pixel circuits are integrated. For example, a 1-1 light-emitting element 130a, a 2-1 light-emitting element 140a, and a 3-1 light-emitting element 150a can be driven by one pixel driving circuit PD in which a plurality of pixel circuits are integrated.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to the pair of first sub-pixels SP1, respectively. The third signal line TL3 and the fourth signal line TL4 can be electrically connected to the pair of second sub-pixels SP2, respectively. The fifth signal line TL5 and the sixth signal line TL6 can be electrically connected to the pair of third sub-pixels SP3, respectively.

The first signal line TL1 can be disposed on one side of the pair of first sub-pixels SP1, and the second signal line TL2 can be disposed on the other side of the pair of first sub-pixels SP1. The first signal line TL1 can be electrically connected to the first electrode CE1 of one of the pair of first sub-pixels SP1, for example, the 1-1 sub-pixel SP1a. The second signal line TL2 can be electrically connected to the first electrode CE1 of the other of the pair of first sub-pixels SP1, for example, the 1-2 sub-pixel SP1b.

The third signal line TL3 can be disposed on one side of the pair of second sub-pixels SP2, and the fourth signal line TL4 can be disposed on the other side of the pair of second sub-pixels SP2. For example, the third signal line TL3 can be disposed adjacent to the second signal line TL2. The third signal line TL3 can be electrically connected to the first electrode CE1 of one of the pair of second sub-pixels SP2, for example, the 2-1 sub-pixel SP2a. The fourth signal line TL4 can be electrically connected to the first electrode CE1 of the other of the pair of second sub-pixels SP2, for example, the 2-2 sub-pixel SP2b.

The fifth signal line TL5 can be disposed on one side of the pair of third sub-pixels SP3, and the sixth signal line TL6 can be disposed on the other side of the pair of third sub-pixels SP3. For example, the fifth signal line TL5 can be disposed adjacent to the fourth signal line TL4. The sixth signal line TL6 can be disposed adjacent to the first signal line TL1 connected to the neighboring pixel PX. The fifth signal line TL5 can be electrically connected to the first electrode CE1 of one of the pair of third sub-pixels SP3, for example, the 3-1 sub-pixel SP3a. The sixth signal line TL6 can be electrically connected to the first electrode CE1 of the other of the pair of third sub-pixels SP3, for example, the 3-2 sub-pixel SP3b.

The plurality of signal lines TL can be formed of a conductive material. For example, the plurality of signal lines TL can be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. For another example, the plurality of signal lines TL can be formed in a multilayer structure of conductive materials. For example, the plurality of signal lines TL can be formed in a multilayer structure of titanium (Ti)/aluminum (Al)/titanium (Ti)/indium tin oxide (ITO), but the embodiments of the present disclosure are not limited thereto.

The plurality of communication lines NL can be disposed in areas between the plurality of pixels PX. The plurality of communication lines NL can be disposed to extend in a row direction in the areas between the plurality of pixels PX. The plurality of communication lines NL are disposed in areas between the plurality of second electrodes CE2 and may not overlap the plurality of second electrodes CE2. For example, the plurality of communication lines NL can be lines used for short-range communication, such as near-field communication (NFC). The plurality of communication lines NL can function as antennas. For example, the plurality of communication lines NL can be a plurality of connection lines or the like, but the embodiments of the present disclosure are not limited thereto.

The first electrode CE1 can be disposed in each of the plurality of sub-pixels. The first electrode CE1 can be disposed on the bank BNK. The first electrode CE1 can be electrically connected to one of the plurality of signal lines TL. At least a portion of the first electrode CE1 can extend outward from the bank BNK to be electrically connected to the signal line TL closest to the first electrode CE1. For example, a portion of the first electrode CE1 of the 1-1 sub-pixel SP1a can extend to one side area of the 1-1 sub-pixel SP1a to be electrically connected to the first signal line TL1, and a portion of the first electrode CE1 of the 1-2 sub-pixel SP1b can extend to the other side area of the 1-2 sub-pixel SP1b to be electrically connected to the second signal line TL2. A portion of the first electrode CE1 of the 2-1 sub-pixel SP2a can extend to one side area of the 2-1 sub-pixel SP2a to be electrically connected to the third signal line TL3, and a portion of the first electrode CE1 of the 2-2 sub-pixel SP2b can extend to the other side area of the 2-2 sub-pixel SP2b to be electrically connected to the fourth signal line TL4. A portion of the first electrode CE1 of the 3-1 sub-pixel SP3a can extend to one side area of the 3-1 sub-pixel SP3a to be electrically connected to the fifth signal line TL5, and a portion of the first electrode CE1 of the 3-2 sub-pixel SP3b can extend to the other side area of the 3-2 sub-pixel SP3b to be electrically connected to the sixth signal line TL6.

The first electrode CE1 can be electrically connected to the anode 134 of the light-emitting element ED, and can transmit the anode voltage output from the pixel driving circuit PD to the light-emitting element ED through the signal line TL. Different voltages can be applied to the first electrode CE1 of each of the plurality of sub-pixels depending on the displayed image. For example, different voltages can be applied to the first electrode CE1 of each of the plurality of sub-pixels. Accordingly, the first electrode CE1 can be a pixel electrode, but the embodiments of the present disclosure are not limited thereto.

The first electrode CE1 can be formed of a conductive material. For example, the first electrodes CE1 can be configured integrally with the plurality of signal lines TL. For example, the first electrodes CE1 can be formed of the same conductive material as the plurality of signal lines TL, but the embodiments of the present disclosure are not limited thereto. For example, the first electrode CE1 can be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. For another example, the first electrode CE1 can be formed in a multilayer structure of conductive materials. For example, the plurality of first electrodes CE1 can be formed in a multilayer structure of titanium (Ti)/aluminum (Al)/titanium (Ti)/indium tin oxide (ITO), but the embodiments of the present disclosure are not limited thereto.

The light-emitting element ED can be disposed in each of the plurality of sub-pixels. Each of the plurality of light-emitting elements ED can be either a light-emitting diode (LED) or a micro light-emitting diode (micro LED), but the embodiments of the present disclosure are not limited thereto. The plurality of light-emitting elements ED can be disposed on the banks BNK and the first electrodes CE1. The plurality of light-emitting elements ED can be disposed on the first electrodes CE1, and can be electrically connected to the first electrodes CE1. Thus, the light-emitting element ED can emit light by receiving the anode voltage from the pixel driving circuit PD through the signal line TL and the first electrode CE1.

The plurality of light-emitting elements ED can include a first light-emitting element 130, a second light-emitting element 140, and a third light-emitting element 150. The first light-emitting element 130 can be disposed in the first sub-pixel SP1. The second light-emitting element 140 can be disposed in the second sub-pixel SP2. The third light-emitting element 150 can be disposed in the third sub-pixel SP3. For example, one of the first light-emitting element 130, the second light-emitting element 140, and the third light-emitting element 150 can be a red light-emitting element, another one thereof can be a green light-emitting element, and the remaining one thereof can be a blue light-emitting element, but the embodiments of the present disclosure are not limited thereto. Accordingly, by combining red light, green light, and blue light emitted from the plurality of light-emitting elements ED, various colors of light including white can be implemented. The types of the plurality of light-emitting elements ED are examples, and the embodiments of the present disclosure are not limited thereto.

The first light-emitting element 130 can include the 1-1 light-emitting element 130a disposed in the 1-1 sub-pixel SP1a and a 1-2 light-emitting element 130b disposed in the 1-2 sub-pixel SP1b. The second light-emitting element 140 can include the 2-1 light-emitting element 140a disposed in the 2-1 sub-pixel SP2a and a 2-2 light-emitting element 140b disposed in the 2-2 sub-pixel SP2b. The third light-emitting element 150 can include the 3-1 light-emitting element 150a disposed in the 3-1 sub-pixel SP3a and a 3-2 light-emitting element 150b disposed in the 3-2 sub-pixel SP3b.

Referring to FIGS. 8A to 8C, in each of the plurality of pixels PX, a plurality of banks BNK can be disposed. The plurality of banks BNK can be structures on which the plurality of light-emitting elements ED are mounted. The plurality of banks BNK can guide positions of the plurality of light-emitting elements ED in a transfer process of transferring the plurality of light-emitting elements ED to the display device 1000. In the transfer process of the plurality of light-emitting elements ED, the plurality of light-emitting elements ED can be transferred onto the plurality of banks BNK.

A first bank BNK1 of the first sub-pixel SP1, a second bank BNK2 of the second sub-pixel SP2, and a third bank BNK3 of the third sub-pixel SP3 can be disposed to be spaced apart from each other. The first bank BNK1 of the first sub-pixel SP1, the second bank BNK2 of the second sub-pixel SP2, and the third bank BNK3 of the third sub-pixel SP3 can be configured to be separated from each other. Thus, the banks BNK of the first sub-pixel SP1, the second sub-pixel SP2, and the third sub-pixel SP3, onto which different types of light-emitting elements ED are transferred, can be easily identified.

A bank BNK of the 1-1 sub-pixel SP1a and a bank BNK of the 1-2 sub-pixel SP1b can be connected to each other, or can be spaced apart from each other or separately formed. For example, considering the design requirements of the transfer process and the like, the bank BNK of the 1-1 sub-pixel SP1a and the bank BNK of the 1-2 sub-pixel SP1b, in which the same type of light-emitting elements ED are disposed, can be connected to each other, or can be spaced apart or separated from each other. In addition, a bank BNK of the 2-1 sub-pixel SP2a and a bank BNK of the 2-2 sub-pixel SP2b can be connected to each other, or can be spaced apart from each other or separately formed. A bank BNK of the 3-1 sub-pixel SP3a and a bank BNK of the 3-2 sub-pixel SP3b can be connected to each other, or can be spaced apart from each other or separately formed. Accordingly, the banks BNK of the pair of first sub-pixels SP1, the banks BNK of the pair of second sub-pixels SP2, and the banks BNK of the pair of third sub-pixels SP3 can be variously formed, but the embodiments of the present disclosure are not limited thereto.

The plurality of banks BNK can have different sizes according to the plurality of light-emitting elements ED mounted thereon. The plurality of banks BNKs can be bank patterns or structures, but the embodiments of the present disclosure are not limited thereto.

The first banks BNK1 can have a size different from that of each of the second and third banks BNK2 and BNK3. For example, the first banks BNK1 can have a greater size than each of the second and third banks BNK2 and BNK3. Accordingly, within one pixel PX, a row-directional spacing between the first bank BNK1 and the second bank BNK2 can be different from a row-directional spacing between the second bank BNK2 and the third bank BNK3.

Since the second bank BNK2 and the third bank BNK3 are smaller than the first bank BNK1, the row-directional spacing between second bank BNK2 and third bank BNK3 can be formed to be greater than the row-directional spacing between first bank BNK1 and second bank BNK2.

In addition, a second spacing D2 between first banks BNK1 disposed in pixels in adjacent columns and a third spacing D3 between first banks BNK1 disposed in pixels in adjacent rows can be different from each other. For example, the second spacing D2 can be formed to be wider than the third spacing D3, but the embodiments of the present disclosure are not limited thereto.

In transferring the light-emitting elements ED onto the plurality of banks BNK, a multi-place (MP) process can be used.

When the light-emitting elements ED are transferred using a multi-place (MP) process, a plurality of first light-emitting elements 130, which emit light in a first wavelength band, can be simultaneously picked up from the wafer 1001 by being attached to the pickup heads 330.

Subsequently, a portion of the first light-emitting elements 130 can be separated from the corresponding pickup heads 330 and transferred onto the substrate 110 at positions corresponding to the 1-1 light-emitting elements 130a of the first banks BNK1.

Thereafter, after moving the pickup heads 330, another portion of the first light-emitting elements 130 can be separated from the corresponding pickup heads 330 and transferred onto the substrate 110 at positions corresponding to the 1-2 light-emitting elements 130b of the first banks BNK1.

In the present disclosure, a case in which the first light-emitting elements 130 are transferred has been described as an example, but the transfer processes of the second and third light-emitting elements 140 and 150 can be substantially the same as the transfer process of the first light-emitting elements 130.

For example, the plurality of banks BNK can be formed of an organic insulating material. The plurality of banks BNK can be formed of a single layer or multiple layers of an organic insulating material. For example, the plurality of banks BNK can be formed of a photoresist, a polyimide (PI)-based material, a photo acrylic-based material, or the like, but the embodiments of the present disclosure are not limited thereto.

Referring to FIG. 9, the second electrode CE2 can be disposed in each of the plurality of sub-pixels. The second electrode CE2 can be disposed on the light-emitting element ED. The second electrodes CE2 can be electrically connected to the pixel driving circuit PD through a plurality of contact electrodes CCE.

For example, the second electrode CE2 can be electrically connected to a cathode 135 of the light-emitting element ED, and can transmit a cathode voltage output from the pixel driving circuit PD to the light-emitting element ED. The same cathode voltage can be applied to the second electrode CE2 of each of the plurality of sub-pixels. For example, the same voltage can be applied to the second electrodes CE2 of the plurality of sub-pixels and the cathode 135 of the light-emitting element ED. Accordingly, the second electrode CE2 can be a common electrode, but the embodiments of the present disclosure are not limited thereto.

At least some of the plurality of sub-pixels can share the second electrode CE2. At least some of the second electrodes CE2 of the plurality of sub-pixels can be electrically connected to each other. Since the same voltage is applied to the second electrodes CE2, the second electrodes CE2 of at least some of the sub-pixels can be shared and used. For example, the second electrodes CE2 of at least some of the plurality of pixels PX disposed in the same row can be connected to each other. For example, one second electrode CE2 can be disposed in the plurality of pixels PX. One second electrode CE2 can be disposed for every n sub-pixels.

For example, some of the second electrodes CE2 of the plurality of sub-pixels can be spaced apart from each other or separately disposed. For example, the second electrodes CE2 connected to the pixels PX in an nth row and the second electrodes CE2 connected to the pixels PX in a (n+1)th row can be spaced apart from each other or separately disposed. For example, the plurality of second electrodes CE2 can be disposed to be spaced apart from each other with the plurality of communication lines NL extending in the row direction interposed therebetween. Accordingly, the number of sub-pixels can be greater than the number of second electrodes CE2. For another example, all of the second electrodes CE2 of the plurality of sub-pixels can be interconnected so that only one second electrode CE2 is disposed on the substrate 110, but the embodiments of the present disclosure are not limited thereto.

The plurality of second electrodes CE2 can be formed of a transparent conductive material, but the embodiments of the present disclosure are not limited thereto. The plurality of second electrodes CE2 can be formed of a transparent conductive material so that light emitted from the light-emitting elements ED is directed upward through the second electrodes CE2. For example, the second electrode CE2 can be formed of a transparent conductive material such as indium tin oxide (ITO), indium zinc oxide (IZO), or indium gallium zinc oxide (IGZO), but the embodiments of the present disclosure are not limited thereto.

The plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap the plurality of contact electrodes CCE.

For example, the plurality of contact electrodes CCE can be electrically connected to the plurality of second electrodes CE2. The plurality of contact electrodes CCE can be disposed between the substrate 110 and the plurality of second electrodes CE2, and can transmit the cathode voltage output from the pixel driving circuit PD to the second electrodes CE2.

For example, when inorganic light-emitting elements are used as the light-emitting elements ED, a plurality of inorganic light-emitting elements can be formed on a wafer and transferred onto the substrate 110 of the display device 1000 to manufacture the display device 1000.

In consideration of the defects that can occur during the transfer of the plurality of light-emitting elements ED, the plurality of light-emitting elements ED of the same type can be transferred onto one sub-pixel. A lighting test can be performed on the plurality of light-emitting elements ED, and ultimately, only one light-emitting element ED that is determined to be normal can be used.

For example, the 1-1 light-emitting element 130a and the 1-2 light-emitting element 130b can be transferred together onto one pixel PX, and can be inspected to determine whether there is a defect. When both the 1-1 light-emitting element 130a and the 1-2 light-emitting element 130b are determined to be normal, only the 1-1 light-emitting element 130a can be used, and the 1-2 light-emitting element 130b may not be used. For another example, when only the 1-1 light-emitting element 130a is normally transferred among the 1-1 light-emitting element 130a and the 1-2 light-emitting element 130b, and the 1-2 light-emitting element 130b is either over-transferred or not transferred, the 1-2 light-emitting element 130b can be unused, and only the 1-1 light-emitting element 130a can be used. Accordingly, even when the plurality of light-emitting elements ED of the same type are transferred onto one pixel PX, ultimately, only one light-emitting element ED can be used.

Thus, one of the pair of light-emitting elements ED can be a main (or primary) light-emitting element ED, and the other one thereof can be a redundancy light-emitting element ED. The redundancy light-emitting element ED can be a spare light-emitting element ED transferred in preparation for a defective main light-emitting element ED. In the event of a defective main light-emitting element ED, the redundancy light-emitting element ED can be used as a replacement. Accordingly, by transferring both the main light-emitting element ED and the redundancy light-emitting element ED onto one pixel PX, the degradation of display quality duc to the failure of the main light-emitting element ED or the redundancy light-emitting element ED can be minimized.

For example, the 1-1 light-emitting element 130a, the 2-1 light-emitting element 140a, and the 3-1 light-emitting element 150a transferred onto one pixel PX can be used as main light-emitting elements ED, and the 1-2 light-emitting element 130b, the 2-2 light-emitting element 140b, and the 3-2 light-emitting element 150b transferred onto one pixel PX can be used as redundancy light-emitting elements ED.

Although a redundancy structure of the first light-emitting element 130 has been described, the second light-emitting element 140 and the third light-emitting element 150 can have substantially the same redundancy structure as the first light-emitting element 130.

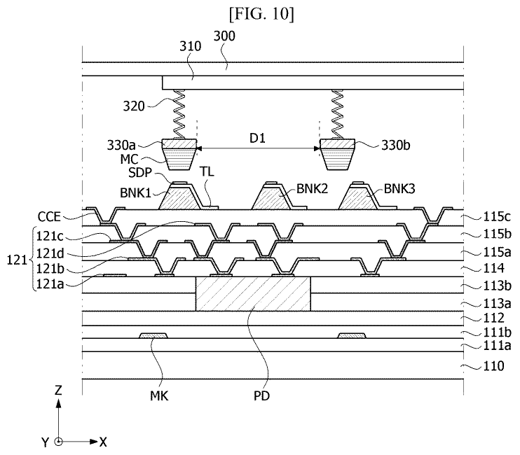

FIGS. 10 to 12 are cross-sectional views illustrating a process of transferring light-emitting elements of the display device according to the present disclosure.

Referring to FIGS. 10 to 12, a first buffer layer 111a and a second buffer layer 111b can be disposed on the substrate 110.

The first buffer layer 111a and the second buffer layer 111b can be disposed in the display area AA, the first non-display area NA1, and the second non-display area NA2. The first buffer layer 111a and the second buffer layer 111b can reduce the penetration of moisture or impurities through the substrate 110. The first buffer layer 111a and the second buffer layer 111b can be formed of an inorganic insulating material. For example, the first buffer layer 111a and the second buffer layer 111b can each be formed as a single layer or multiple layers of silicon oxide (SiOₓ) or silicon nitride (SiNₓ), but the embodiments of the present disclosure are not limited thereto.

For example, some of the first buffer layer 111a and the second buffer layer 111b located in a bending area BA can be removed. An upper surface of the substrate 110 located in the bending area BA can be exposed from the first buffer layer 111a and the second buffer layer 111b. The first buffer layer 111a and the second buffer layer 111b, which are formed of an inorganic insulating material, can be removed from the bending area BA to minimize cracks that can occur in the first buffer layer 111a and the second buffer layer 111b during bending.

A plurality of alignment keys MK can be disposed between the first buffer layer 111a and the second buffer layer 111b. The plurality of alignment keys MK can be configured to identify the position of the pixel driving circuit PD during the manufacturing process of the display device 1000.

An adhesive layer 112 can be disposed on the second buffer layer 111b. The adhesive layer 112 can be disposed in the display area AA, the first non-display area NA1, the bending area BA, and the second non-display area NA2. For another example, at least a portion of the adhesive layer 112 can be removed from the non-display area NA including the bending area BA. For example, the adhesive layer 112 can be formed of any one of an adhesive polymer, an epoxy resin, an ultraviolet (UV)-curable resin, a polyimide-based material, an acrylate-based material, a urethane-based material, and polydimethylsiloxane (PDMS), but the embodiments of the present disclosure are not limited thereto.

In the display area AA, the pixel driving circuit PD can be disposed on the adhesive layer 112. When the pixel driving circuit PD is implemented as a micro driver, the micro driver can be mounted on the adhesive layer 112 through a transfer process. The pixel driving circuit PD disposed on the adhesive layer 112 can be manufactured using a MOSFET fabrication process on a semiconductor substrate and then transferred. The plurality of alignment keys MK can be configured during the manufacturing process of the display device 1000 to identify the position of the pixel driving circuit PD, thereby enabling accurate alignment of the pixel driving circuit PD during transfer. For example, four alignment keys MK can be disposed for one pixel driving circuit PD so that each pixel driving circuit PD can be aligned at a position to be mounted. However, the embodiments of the present disclosure are not limited thereto, and the position of the pixel driving circuit PD can be identified and pixel driving circuit PD can be transferred using two or one alignment key MK.

A first protective layer 113a and a second protective layer 113b can be disposed on the adhesive layer 112 and the pixel driving circuit PD. The first protective layer 113a and the second protective layer 113b can be disposed to surround side surfaces of the pixel driving circuit PD, but the embodiments of the present disclosure are not limited thereto. For example, the second protective layer 113b can be disposed to cover at least a portion of an upper surface of the pixel driving circuit PD. For example, at least one of the first protective layer 113a and the second protective layer 113b disposed in the bending area BA can be omitted. For example, the first protective layer 113a can be entirely disposed in the display area AA and the non-display area NA, and the second protective layer 113b can be partially disposed in the display area AA, the first non-display area NA1, and the second non-display area NA2. For example, a portion of the second protective layer 113b in the bending area BA can be removed. However, the embodiments of the present disclosure are not limited thereto.

The first protective layer 113a and the second protective layer 113b can be formed of an organic insulating material, but the embodiments of the present disclosure are not limited thereto. For example, the first protective layer 113a and the second protective layer 113b can be formed of a photoresist, a polyimide (PI)-based material, a photo acrylic-based material, or the like, but the embodiments of the present disclosure are not limited thereto. For example, the first protective layer 113a and the second protective layer 113b can each be an overcoating layer or an insulating layer, but the embodiments of the present disclosure are not limited thereto.

According to the present disclosure, a plurality of first connection lines 121 can be disposed on the second protective layer 113b in the display area AA. The plurality of first connection lines 121 can be lines for electrically connecting the pixel driving circuit PD to other components. For example, the pixel driving circuit PD can be electrically connected to the plurality of signal lines TL, the plurality of contact electrodes CCE, and the like through the plurality of first connection lines 121. For example, the plurality of first connection lines 121 can include a 1-1 connection line 121a, a 1-2 connection line 121b, a 1-3 connection line 121c, and a 1-4 connection line 121d, but the embodiments of the present disclosure are not limited thereto.

For example, a plurality of 1-1 connection lines 121a can be disposed on the second protective layer 113b. The plurality of 1-1 connection lines 121a can be electrically connected to the pixel driving circuit PD. The plurality of 1-1 connection lines 121a can transmit a voltage output from the pixel driving circuit PD to the first electrode CE1 or the second electrode CE2.

For example, a third protective layer 114 can be disposed on the second protective layer 113b. The third protective layer 114 can be entirely disposed in the display area AA and the non-display area NA. In the bending area BA, the third protective layer 114 can cover a side surface of the second protective layer 113b and an upper surface of the first protective layer 113a. The third protective layer 114 can be formed of an organic insulating material. For example, the third protective layer 114 can be formed of a photoresist, a polyimide (PI)-based material, a photo acrylic-based material, or the like, but the embodiments of the present disclosure are not limited thereto. For example, the first protective layer 113a, the second protective layer 113b, and the third protective layer 114 can be formed of the same material, however, the embodiments of the present disclosure are not limited thereto.

A plurality of 1-2 connection lines 121b can be disposed on the third protective layer 114. The plurality of 1-2 connection lines 121b can be connected to or directly connected to the pixel driving circuit PD. For example, some of the 1-2 connection lines 121b can be directly connected to the pixel driving circuit PD through contact holes of the third protective layer 114. Another part of the 1-2 connection lines 121b can be electrically connected to the 1-1 connection line 121a through contact holes of the third protective layer 114. However, the embodiments of the present disclosure are not limited thereto. The voltage output from the pixel driving circuit PD can be transmitted to the first electrode CE1 or the second electrode CE2 through the plurality of 1-2 connection lines 121b and other connection lines.

A first insulating layer 115a can be disposed on the plurality of 1-2 connection lines 121b. The first insulating layer 115a can be entirely disposed in the display area AA and the non-display area NA, but the embodiments of the present disclosure are not limited thereto. The first insulating layer 115a can be formed of an organic insulating material, but the embodiments of the present disclosure are not limited thereto. For example, the first insulating layer 115a can be formed of a photoresist, a polyimide (PI)-based material, a photo acrylic-based material, or the like, but the embodiments of the present disclosure are not limited thereto.

A plurality of 1-3 connection lines 121c can be disposed on the first insulating layer 115a. The plurality of 1-3 connection lines 121c can be electrically connected to the plurality of 1-2 connection lines 121b. For example, the 1-3 connection lines 121c can be electrically connected to the 1-2 connection lines 121b through contact holes of the first insulating layer 115a.

A second insulating layer 115b can be disposed on the plurality of 1-3 connection lines 121c. The second insulating layer 115b can be disposed in the remaining area excluding the bending area BA, but the embodiments of the present disclosure are not limited thereto. The second insulating layer 115b can be disposed in the display area AA, the first non-display area NA1, and the second non-display area NA2, but the embodiments of the present disclosure are not limited thereto. For example, a portion of the second insulating layer 115b disposed in the bending area BA can be removed. The second insulating layer 115b can be formed of an organic insulating material, but the embodiments of the present disclosure are not limited thereto. For example, the second insulating layer 115b can be formed of a photoresist, a polyimide (PI)-based material, a photo acrylic-based material, or the like, but the embodiments of the present disclosure are not limited thereto.

A plurality of 1-4 connection lines 121d can be disposed on the second insulating layer 115b. The plurality of 1-4 connection lines 121d can be electrically connected to the plurality of 1-3 connection lines 121c. For example, the 1-4 connection lines 121d can be electrically connected to the 1-3 connection lines 121c through contact holes of the second insulating layer 115b.

In the display area AA, a plurality of banks BNK can be disposed on the third insulating layer 115c. The plurality of banks BNK can be disposed to overlap the plurality of sub-pixels, respectively. At least one or more light-emitting elements ED of the same type can be disposed on each of the plurality of banks BNK.

A plurality of signal lines TL can be disposed on the third insulating layer 115c in the display area AA. The plurality of signal lines TL can be disposed in an area between the plurality of banks BNK. For example, the plurality of signal lines TL can be disposed adjacent to any one of the plurality of banks BNK.

A plurality of contact electrodes CCE can be disposed on the third insulating layer 115c in the display area AA. The plurality of contact electrodes CCE can supply a cathode voltage output from the pixel driving circuit PD to the second electrode CE2.

The first electrode CE1 can be disposed on the bank BNK. For example, the first electrode CE1 can be disposed to extend toward an upper portion of the bank BNK from the adjacent signal line TL. The first electrode CE1 can be disposed on upper and side surfaces of the bank BNK. For example, the first electrode CE1 can be disposed to extend from the signal line TL on an upper surface of the third insulating layer 115c to the side and upper surfaces of the bank BNK.

Among a plurality of conductive layers forming the first electrode CE1 disposed on the bank BNK, some conductive layers with high reflectivity can be configured as alignment keys and/or reflectors for aligning the light-emitting element ED.

After the elements MC, which have undergone a manufacturing process on a wafer, are picked up by the pickup heads 330 of the transfer substrate 300 and transferred, the elements MC can be transferred onto solder patterns SDP of the banks BNK by using some conductive layers as alignment keys for aligning the light-emitting element ED.

Various defects can occur during the process of transferring a plurality of elements MC having a micro size onto the solder patterns SDP of the banks BNK from the wafer. For example, in some sub-pixels, a transfer defect can occur in which the element MC is not transferred, and in other sub-pixels, a defect can occur in which the element MC is transferred out of an intended position due to misalignment.

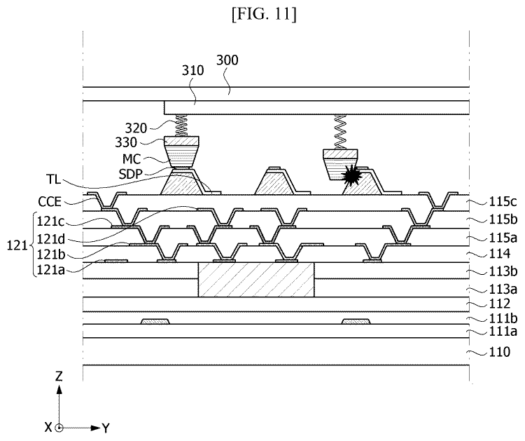

In particular, as shown in FIG. 11, when transferring the light-emitting elements MC onto the banks BNK using a multi-place MP process, a larger number of light-emitting elements MC are picked up by a plurality of pickup heads 330 in a single pickup operation from the wafer 1001 than the number of light-emitting elements MC to be transferred in a single transfer operation, in order to enable multiple transfers from one pickup.

The spacing D1 between adjacent pickup heads 330 can be formed to be smaller than each of the spacings D2 and D3 between the banks BNK on which the transfer is to be performed. When the spacing D1 between adjacent pickup heads 330 is formed to be smaller than the spacing between banks BNK for transfer, the element MC that is not intended to be transferred can collide with a side surface of the bank disposed therebelow during the transfer process, thereby causing a defect such as an erroneous transfer defect.

Such a defect can occur during the transfer of the first light-emitting element 130, which has the largest size among the elements MC.

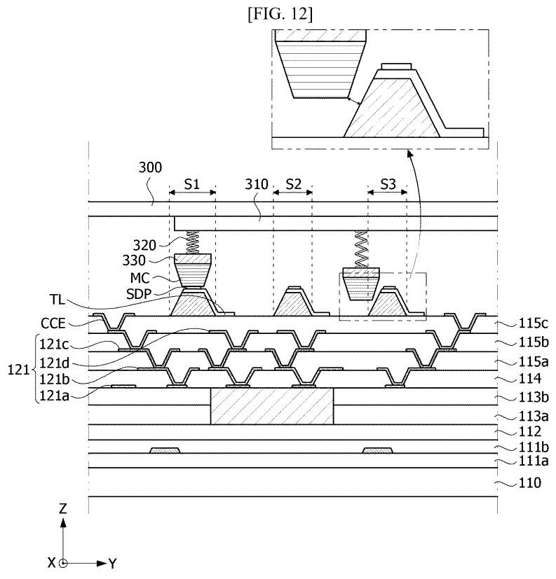

Referring to FIG. 12, sizes S2 and S3 of the second and third banks BNK2 and BNK3, onto which the second and third light-emitting elements 140 and 150 are respectively transferred, can each be formed to be smaller than a size S1 of the first bank BNK1.

By forming the sizes of the second and third banks BNK2 and BNK3 to be smaller than the size S1 of the first bank BNK1, a margin can be secured between the element MC and the bank BNK during the transfer of the first light-emitting elements 130, thereby preventing a defect in which the element collides with the bank.

The sizes S2 and S3 of the second and third banks BNK2 and BNK3 can be substantially the same. However, the embodiments of the present disclosure are not limited thereto.

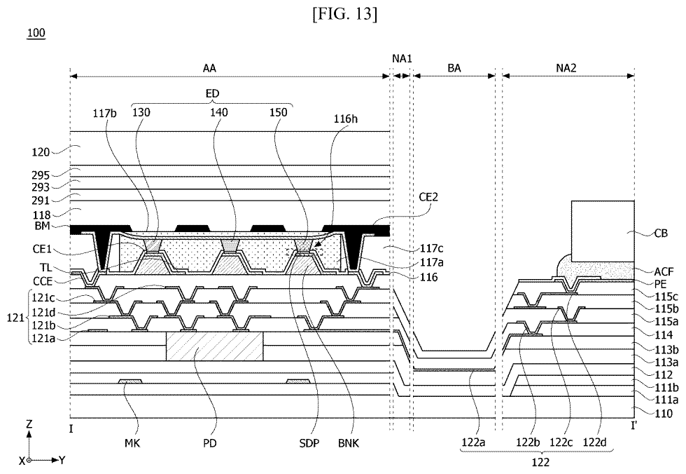

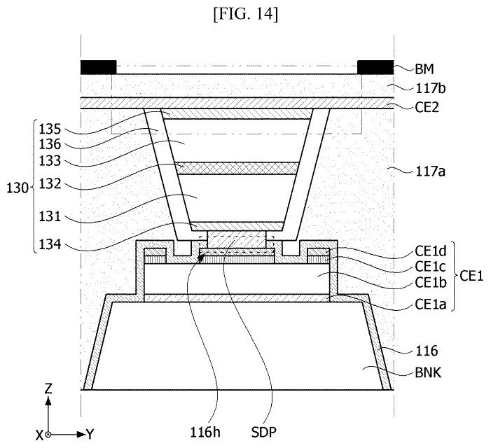

FIG. 13 is a cross-sectional view of the display device according to the embodiment of the present disclosure, taken along line I-I′ of FIG. 3. FIG. 14 is a cross-sectional view illustrating the sub-pixel including the light-emitting element disposed in the display area AA.

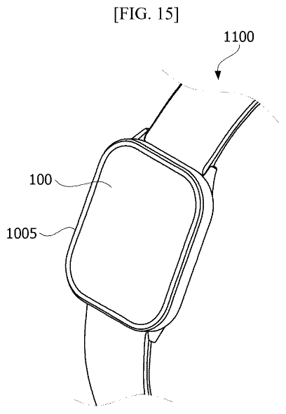

FIG. 15 is a cross-sectional view of the display area AA, the first non-display area NA1, the bending area BA, and the second non-display area NA2.

Referring to FIG. 13, a passivation layer 116 can be disposed on the plurality of signal lines TL, the plurality of first electrodes CE1, the plurality of contact electrodes CCE, and the third insulating layer 115c. For example, the passivation layer 116 can be disposed in the display area AA, the first non-display area NA1, and the second non-display area NA2. A portion of the passivation layer 116 disposed in the bending area BA can be removed. In the second non-display area NA2, a portion of the passivation layer 116 covering the plurality of pad electrodes PE can be removed. The passivation layer 116 can be disposed to cover remaining areas except for the bending area BA, the area in which the plurality of pad electrodes PE and the solder pattern SDP are disposed, thereby reducing the penetration of moisture or impurities into the light-emitting element ED. For example, the passivation layer 116 can be formed as a single layer or multiple layers of silicon oxide (SiOₓ) or silicon nitride (SiNₓ), but the embodiments of the present disclosure are not limited thereto. For example, the passivation layer 116 can be a protective layer, an insulating layer, or the like, but the embodiments of the present disclosure are not limited thereto. For example, the passivation layer 116 can include an opening 116h that exposes the solder pattern SDP.

In each of the plurality of sub-pixels, the light-emitting element ED can be disposed on the solder pattern SDP. In the first sub-pixel SP1, the first light-emitting element 130 can be disposed. In the second sub-pixel SP2, the second light-emitting element 140 can be disposed. The third light-emitting element 150 disposed in the third sub-pixel SP3.

The light-emitting element ED can be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present disclosure are not limited thereto.

The first electrode CE1 can be formed of a plurality of conductive layers. For example, the first electrode CE1 can include a first conductive layer CE1a, a second conductive layer CE1b, a third conductive layer CE1c, and a fourth conductive layer CE1d, but the embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, the first conductive layer CE1a, the second conductive layer CE1b, the third conductive layer CE1c, and the fourth conductive layer CE1d can each be formed of titanium (Ti), molybdenum (Mo), aluminum (Al), or indium tin oxide (ITO), but the embodiments of the present disclosure are not limited thereto.

According to the present disclosure, among the plurality of conductive layers forming the first electrode CE1, some conductive layers with high reflectivity can be configured as alignment keys and/or reflectors for the alignment of the light-emitting element ED. For example, among the plurality of conductive layers of the first electrode CE1, the second conductive layer CE1b can include a reflective material. For example, the second conductive layer CE1b can include aluminum (Al), but the embodiments of the present disclosure are not limited thereto. Accordingly, the second conductive layer CE1b can be configured as a reflector. Further, due to the high reflectivity of the second conductive layer CE1b, identification can be facilitated in the manufacturing process, thereby allowing the position or transfer position of the light-emitting element ED to be aligned based on the second conductive layer CE1b.

For example, to configure the second conductive layer CE1b as a reflector, the third conductive layer CE1c and the fourth conductive layer CE1d covering the second conductive layer CE1b can be partially removed or etched. For example, some of the third conductive layer CE1c and the fourth conductive layer CE1d disposed on the banks BNK can be removed or etched to expose an upper surface of the second conductive layer CE1b. For example, in each of the third conductive layer CE1c and the fourth conductive layer CE1d, a central portion on which the solder pattern SDP is disposed and edge portions can be retained, whereas the remaining portions can be removed. For example, the edge portions of each of the third conductive layer CE1c, which is formed of titanium (Ti), and the fourth conductive layer CE1d, which is formed of indium tin oxide (ITO), may not be etched. Accordingly, it is possible to prevent other conductive layers of the first electrode CE1 from being corroded by a tetramethylammonium hydroxide (TMAH) solution used in the masking process of the first electrode CE1.

According to the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned through a photolithography process and an etching process, but the embodiments of the present disclosure are not limited thereto.

According to the present disclosure, the signal line TL, contact electrode CCE, and pad electrode PE, which are disposed on the same layer as the first electrode CE1, can be formed as multiple layers of conductive materials, but the embodiments of the present disclosure are not limited thereto. For example, the signal line TL, the contact electrode CCE, and the pad electrode PE can be formed as multiple layers of indium tin oxide (ITO)/titanium (Ti)/aluminum (Al)/titanium (Ti), but the embodiments of the present disclosure are not limited thereto.

According to the present disclosure, the solder pattern SDP can be disposed on the first electrode CE1 in each of the plurality of sub-pixels. The solder pattern SDP can allow the light-emitting element ED to be bonded to the first electrode CE1. The first electrode CE1 and the light-emitting element ED can be electrically connected through eutectic bonding using the solder pattern SDP, but the embodiments of the present disclosure are not limited thereto. For example, when the solder pattern SDP is formed of indium (In) and the anode 134 of the light-emitting element ED is formed of gold (Au), the solder pattern SDP and the anode 134 can be bonded by applying heat and pressure during the transfer process of the light-emitting element ED. Through eutectic bonding, the light-emitting element ED can be bonded to the solder pattern SDP and the first electrode CE1 without any additional adhesive. For example, the solder pattern SDP can be formed of indium (In), tin (Sn), or an alloy thereof, but the embodiments of the present disclosure are not limited thereto. For example, the solder pattern SDP can be a bonding pad, a joining pad, or the like, but the embodiments of the present disclosure are not limited thereto.

A first optical layer 117a surrounding the plurality of light-emitting elements ED can be disposed in the display area AA. For example, the first optical layer 117a can be disposed to cover the plurality of light-emitting elements ED and the banks BNK in the areas of the plurality of sub-pixels. For example, the first optical layer 117a can cover the banks BNK, a portion of the passivation layer 116, and a space between the plurality of light-emitting elements ED. The first optical layer 117a can be disposed or can cover the spaces between the plurality of light-emitting elements ED included in one pixel PX and between the plurality of banks BNK. For example, the first optical layer 117a can extend in a first direction (X-axis direction) and can be disposed spaced apart in a second direction (Y-axis direction). For example, the first optical layer 117a can be disposed to surround the side portions of the light-emitting element ED and the bank BNK between the passivation layer 116 and the second electrode CE2, but the embodiments of the present disclosure are not limited thereto. For example, the first optical layer 117a can be a diffusion layer, a sidewall diffusion layer, or the like, but the embodiments of the present disclosure are not limited thereto.

The first optical layer 117a can include an organic insulating material in which fine particles are dispersed, but the embodiments of the present disclosure are not limited thereto. For example, the first optical layer 117a can be formed of siloxane in which fine metal particles, such as titanium dioxide (TiO₂) particles, are dispersed, but the embodiments of the present disclosure are not limited thereto. Light emitted from the plurality of light-emitting elements ED can be scattered by the fine particles dispersed in the first optical layer 117a and emitted to the outside of the display device 1000. Accordingly, the first optical layer 117a can improve the extraction efficiency of the light emitted from the plurality of light-emitting elements ED.

For example, the first optical layer 117a can be disposed in each of the plurality of pixels PX, or the first optical layer 117a can be disposed together with some of the pixels PX disposed in the same row, but the embodiments of the present disclosure are not limited thereto. For example, the first optical layer 117a can be disposed in each of the plurality of pixels PX, or the plurality of pixels PX can share one first optical layer 117a. For another example, each of the plurality of sub-pixels can separately include the first optical layer 117a, but the embodiments of the present disclosure are not limited thereto.

According to the present disclosure, a third optical layer 117c can be disposed on the passivation layer 116 in the display area AA. For example, the third optical layer 117c can be disposed to surround the first optical layer 117a. For example, the third optical layer 117c can be in contact with a side surface of the first optical layer 117a. For example, the third optical layer 117c can be disposed in the area between the plurality of pixels PX. However, the embodiments of the present disclosure are not limited thereto, and for example, the third optical layer 117c can be a diffusion layer, a diffusion layer window, a window diffusion layer, or the like, but the embodiments of the present disclosure are not limited thereto.

The third optical layer 117c can be formed of an organic insulating material, but the embodiments of the present disclosure are not limited thereto. The third optical layer 117c can be formed of the same material as the first optical layer 117a, but the embodiments of the present disclosure are not limited thereto. For example, the first optical layer 117a can include fine particles, and the third optical layer 117c may not include fine particles. For example, the third optical layer 117c can be formed of siloxane, but the embodiments of the present disclosure are not limited thereto.

For example, a thickness of the first optical layer 117a can be smaller than a thickness of the third optical layer 117c, but the embodiments of the present disclosure are not limited thereto. Accordingly, when viewed in a plan view, an area in which the first optical layer 117a is disposed can include a recessed portion that is recessed inward relative to an upper surface of the third optical layer 117c.

According to the present disclosure, the second electrode CE2 can be disposed on the first optical layer 117a and the third optical layer 117c. For example, the second electrode CE2 can be electrically connected to the plurality of contact electrodes CCE through a contact hole of the third optical layer 117c. For example, the second electrode CE2 can be disposed on the plurality of light-emitting elements ED. For example, the second electrode CE2 can include a transparent conductive oxide such as indium tin oxide (ITO) or indium zinc oxide (IZO), but the embodiments of the present disclosure are not limited thereto. For example, the second electrode CE2 can be disposed to be in contact with the cathode 135. For example, the second electrode CE2 can overlap the first optical layer 117a. For example, the second electrode CE2 can cover an outer plane of the first optical layer 117a.

The second electrode CE2 can continuously extend in the first direction (X-axis direction) of the substrate 110. Accordingly, the second electrode CE2 can be commonly connected to the plurality of pixels PX arranged in the first direction X of the substrate 110. For example, the second electrode CE2 can be commonly connected to a plurality of pixels PX.

According to the present disclosure, the second electrode CE2 can continuously extend on the first optical layer 117a, the third optical layer 117c, and the light-emitting element ED. The area in which the first optical layer 117a is disposed can include a recessed portion that is recessed inward relative to the upper surface of the third optical layer 117c. Accordingly, since a first portion of the second electrode CE2 disposed on the first optical layer 117a is disposed along the recessed portion, the first portion of the second electrode CE2 can be disposed at a position lower than a second portion of the second electrode CE2 disposed on the third optical layer 117c.

A second optical layer 117b can be disposed on the second electrode CE2. The second optical layer 117b can be disposed to overlap the plurality of light-emitting elements ED and the first optical layer 117a. Since the second optical layer 117b is disposed on the second electrode CE2 and the plurality of light-emitting elements ED, the second optical layer 117b can improve the mura that can occur in some of the plurality of light-emitting elements ED. For example, when transferring the plurality of light-emitting elements ED onto the substrate 110 of the display device 1000, an area in which intervals between the plurality of light-emitting elements ED are not uniform can occur due to process variations or the like. When the intervals between the plurality of light-emitting elements ED are not uniform, light emission areas of each of the plurality of light-emitting elements ED can be disposed unevenly, which can cause a user to perceive mura. Accordingly, by configuring the second optical layer 117b to uniformly diffuse light over the plurality of light-emitting elements ED, the occurrence of light emitted from some light-emitting elements ED appearing as mura can be reduced. Accordingly, the light emitted from the plurality of light-emitting elements ED is evenly diffused by the second optical layer 117b and extracted to the outside of the display device 1000, thereby improving the luminance uniformity of the display device 1000.

The second optical layer 117b can be formed of an organic insulating material in which fine particles are dispersed, but the embodiments of the present disclosure are not limited thereto. For example, the second optical layer 117b can be formed of siloxane in which fine metal particles, such as titanium dioxide (TiO₂) particles, are dispersed, but the embodiments of the present disclosure are not limited thereto. For example, the second optical layer 117b can be formed of the same material as the first optical layer 117a, but the embodiments of the present disclosure are not limited thereto. For example, the second optical layer 117b can be a diffusion layer, an upper diffusion layer, or the like, but the embodiments of the present disclosure are not limited thereto.

According to the present disclosure, light emitted from the plurality of light-emitting elements ED can be scattered by the fine particles dispersed in the second optical layer 117b and emitted to the outside of the display device 1000. The second optical layer 117b can evenly mix the light emitted from the plurality of light-emitting elements ED, thereby further improving the luminance uniformity of the display device 1000. In addition, the light extraction efficiency of the display device 1000 can be improved by the light scattered from the plurality of fine particles, thereby enabling the display device 1000 to operate at lower power.

In the display area AA, the black matrix BM can be disposed on the second electrode CE2, the first optical layer 117a, the second optical layer 117b, and the third optical layer 117c. For example, the contact hole of the third optical layer 117c can be filled with the black matrix BM. The black matrix BM is configured to cover the display area AA, and thus can reduce the color mixing of light from the plurality of sub-pixels and the reflection of external light. For example, the black matrix BM is also disposed in a contact hole in which the second electrode CE2 and the contact electrode CCE are connected, and thus can prevent light leakage between the plurality of adjacent sub-pixels.

For example, the black matrix BM can be formed of an opaque material, but the embodiments of the present disclosure are not limited thereto. For example, the black matrix BM can be an organic insulating material containing a black pigment or a black dye, but the embodiments of the present disclosure are not limited thereto.

In the display area AA, a cover layer 118 can be disposed on the black matrix BM. The cover layer 118 can protect the configuration below the cover layer 118, and for example, the cover layer 118 can be formed of an organic insulating material, but the embodiments of the present disclosure are not limited thereto. For example, the cover layer 118 can be formed of a photoresist, a polyimide (PI)-based material, a photo acrylic-based material, or the like, but the embodiments of the present disclosure are not limited thereto. For example, the cover layer 118 can be an overcoating layer, an insulating layer, or the like, but the embodiments of the present disclosure are not limited thereto.

The polarizing layer 293 can be disposed on the cover layer 118 via a first adhesive layer 291. The cover member 120 can be disposed on the polarizing layer 293 through the second adhesive layer 295. For example, the first adhesive layer 291 and the second adhesive layer 295 can include an optically clear adhesive (OCA), an optically clear resin (OCR), a pressure sensitive adhesive (PSA), or the like, but the embodiments of the present disclosure are not limited thereto.

According to the present disclosure, a plurality of second connection lines 122 can be disposed on the second protective layer 113b in the non-display area NA. The plurality of second connection lines 122 can be lines for transmitting signals, which are transmitted from the flexible circuit board (or flexible film) CB and the printed circuit board 160 (see FIG. 1) to the pad part PAD, to the pixel driving circuit PD of the display area AA. For example, the plurality of second connection lines 122 can be electrically connected to the plurality of pad electrodes PE to receive the signals output from the flexible circuit board (or flexible film) CB and the printed circuit board.

For example, the plurality of second connection lines 122 can extend from the pad part PAD toward the display area AA and can transmit signals to the lines of the display area AA. In this case, the plurality of second connection lines 122 can function as the link lines LL. The plurality of second connection lines 122 can include a 2-1 connection line 122a, a 2-2 connection line 122b, a 2-3 connection line 122c, and a 2-4 connection line 122d.

A plurality of 2-1 connection lines 122a can be disposed on the second protective layer 113b. A plurality of 2-1 connection lines 122a can be electrically connected with a plurality of 1-2 connection lines 121b in the display area AA. The plurality of 2-1 connection lines 122a can extend from the second non-display area NA2 to the bending area BA and the first non-display area NA1. The plurality of 2-1 connection lines 122a can transmit signals, which are transmitted to the pad part PAD from the flexible circuit board (or flexible film) CB and the printed circuit board, to the pixel driving circuit PD of the display area AA.

A plurality of 2-2 connection lines 122b can be disposed on the third protective layer 114. The plurality of 2-2 connection lines 122b can be disposed in the second non-display area NA2. The 2-2 connection lines 122b can be electrically connected to the 2-1 connection lines 122a through contact holes of the third protective layer 114. Accordingly, the signals output from the flexible circuit board (or flexible film) CB and the printed circuit board can be transmitted to the 2-1 connection lines 122a through the 2-2 connection lines 122b.

The 2-3 connection line 122c can be disposed on the first insulating layer 115a. The 2-3 connection line 122c can be disposed in the second non-display area NA2. The 2-3 connection line 122c can be electrically connected to the 2-2 connection line 122b through a contact hole of the first insulating layer 115a. Accordingly, the signals output from the flexible circuit board (or flexible film) CB and the printed circuit board can be transmitted to the 2-1 connection lines 122a through the 2-3 connection line 122c and the 2-2 connection lines 122b.

The 2-4 connection line 122d can be disposed on the second insulating layer 115b. The 2-4 connection line 122d can be disposed in the second non-display area NA2. The 2-4 connection line 122d can be electrically connected to the 2-3 connection line 122c through the contact hole of the second insulating layer 115b. Accordingly, the signals output from the flexible circuit board (or flexible film) CB and the printed circuit board can be transmitted to the 2-1 connection lines 122a through the 2-4 connection line 122d, the 2-3 connection line 122c, and the 2-2 connection lines 122b.

The plurality of first connection lines 121 and the plurality of second connection lines 122 can be formed of a highly flexible conductive material or any of the various conductive materials used in the display area AA. For example, the second connection lines 122, some of which are disposed in the bending area BA, can be formed of a highly flexible conductive material such as gold (Au), silver (Ag), or aluminum (Al), but the embodiments of the present disclosure are not limited thereto. For another example, the plurality of first connection lines 121 and the plurality of second connection lines 122 can be formed of molybdenum (Mo), chromium (Cr), titanium (Ti), nickel (Ni), neodymium (Nd), copper (Cu), an alloy of silver (Ag) and magnesium (Mg), alloys thereof, or the like, but the embodiments of the present disclosure are not limited thereto.

A third insulating layer 115c can be disposed on the plurality of first connection lines 121 and the plurality of second connection lines 122. The third insulating layer 115c can be disposed in the remaining area excluding the bending area BA, but the embodiments of the present disclosure are not limited thereto. The third insulating layer 115c can be disposed in the display area AA, the first non-display area NA1, and the second non-display area NA2. A portion of the third insulating layer 115c in the bending area BA can be removed. The third insulating layer 115c can be formed of an organic insulating material, but the embodiments of the present disclosure are not limited thereto. For example, the third insulating layer 115c can be formed of a photoresist, a polyimide (PI)-based material, a photo acrylic-based material, or the like, but the embodiments of the present disclosure are not limited thereto.

According to the present disclosure, a plurality of pad electrodes PE can be disposed on the third insulating layer 115c in the second non-display area NA2. For example, at least some of the plurality of pad electrodes PE can be exposed from the passivation layer 116. For example, the plurality of pad electrodes PE can be electrically connected to the 2-4 connection line 122d through contact holes of the third insulating layer 115c.

An adhesive layer ACF can be disposed on the plurality of pad electrodes PE. The adhesive layer ACF can be an adhesive layer in which conductive balls are dispersed in an insulating material, but the embodiments of the present disclosure are not limited thereto. When heat or pressure is applied to the adhesive layer ACF, the conductive balls at the portions to which the heat or pressure is applied can become electrically connected, thereby exhibiting conductive properties. The adhesive layer ACF can be disposed between the plurality of pad electrodes PE and the flexible circuit board (or flexible film) CB, thereby allowing the flexible circuit board (or flexible film) CB to be attached or bonded to the plurality of pad electrodes PE. For example, the adhesive layer ACF can be an anisotropic conductive film (ACF), but the embodiments of the present disclosure are not limited thereto.

The flexible circuit board (or flexible film) CB can be disposed on the adhesive layer ACF. The flexible circuit board (or flexible film) CB can be electrically connected to the plurality of pad electrodes PE through the adhesive layer ACF. Accordingly, signals output from the flexible circuit board (or flexible film) CB and the printed circuit board can be transmitted to the pixel driving circuit PD of the display area AA through the plurality of pad electrodes PE, and the 2-4 connection line 122d, the 2-3 connection line 122c, the 2-2 connection line 122b, and the 2-1 connection line 122a.

Referring to FIG. 14, the first light-emitting element 130 can include an anode 134, a first semiconductor layer 131, an active layer 132, a second semiconductor layer 133, a cathode 135, and an encapsulation film 136, but the embodiments of the present disclosure are not limited thereto. For example, the first light-emitting element 130 may not include the encapsulation film 136.

The first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented as a group III-V compound semiconductor, a group II-VI compound semiconductor, or the like and can be doped with impurities (or dopants). For example, one of the first semiconductor layer 131 and the second semiconductor layer 133 can be a semiconductor layer doped with n-type impurities, and the other can be a semiconductor layer doped with p-type impurities, but the embodiments of the present disclosure are not limited thereto. For example, one or more of the first semiconductor layer 131 and the second semiconductor layer 133 can be a layer doped with n-type or p-type impurities in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like, but the embodiments of the present disclosure are not limited thereto. For example, the n-type impurities can include silicon (Si), germanium (Ge), selenium (Se), carbon (C), tellurium (Te), tin (Sn), and the like, but the embodiments of the present disclosure are not limited thereto. For example, the p-type impurities can include magnesium (Mg), zinc (Zn), calcium (Ca), strontium (Sr), barium (Ba), beryllium (Be), and the like, but the embodiments of the present disclosure are not limited thereto.

For example, the first semiconductor layer 131 and the second semiconductor layer 133 can be a nitride semiconductor containing n-type impurities and a nitride semiconductor containing p-type impurities, respectively, but the embodiments of the present disclosure are not limited thereto. For example, the first semiconductor layer 131 can be a nitride semiconductor containing p-type impurities, and the second semiconductor layer 133 can be a nitride semiconductor containing n-type impurities, but the embodiments of the present disclosure are not limited thereto.

The active layer 132 can be disposed between the first semiconductor layer 131 and the second semiconductor layer 133. The active layer 132 can emit light by receiving holes and electrons from the first semiconductor layer 131 and the second semiconductor layer 133. For example, the active layer 132 can include one of a single well structure, a multi-well structure, a single quantum well structure, a multi-quantum well (MQW) structure, a quantum dot structure, and a quantum wire structure, but the embodiments of the present disclosure are not limited thereto. For example, the active layer 132 can be formed of indium gallium nitride (InGaN), gallium nitride (GaN), or the like, but the embodiments of the present disclosure are not limited thereto.

For another example, the active layer 132 can include a multi-quantum well (MQW) structure having a well layer and a barrier layer with a higher bandgap than the well layer. For example, the active layer 132 can include an InGaN well layer and an AlGaN barrier layer, but the embodiments of the present disclosure are not limited thereto.

The anode 134 can be disposed between the first semiconductor layer 131 and the solder pattern SDP. For example, the anode 134 can electrically connect the first semiconductor layer 131 and the first electrode CE1. An anode voltage output from the pixel driving circuit PD can be applied to the first semiconductor layer 131 through the signal line TL, the first electrode CE1, and the anode 134. For example, the anode 134 can be formed of a conductive material capable of eutectic bonding with the solder pattern SDP, but the embodiments of the present disclosure are not limited thereto. For example, the anode 134 can be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present disclosure are not limited thereto.

The cathode 135 can be disposed on the second semiconductor layer 133. For example, the cathode 135 can electrically connect the second semiconductor layer 133 and the second electrode CE2. A cathode voltage output from the pixel driving circuit PD can be applied to the second semiconductor layer 133 through the contact electrode CCE, the second electrode CE2, and the cathode 135. The cathode 135 can be formed of a transparent conductive material to allow light emitted from the light-emitting element ED to be directed upward, but the embodiments of the present disclosure are not limited thereto. For example, the cathode 135 can be formed of a material such as indium tin oxide (ITO), indium zinc oxide (IZO), or indium gallium zinc oxide (IGZO), but the embodiments of the present disclosure are not limited thereto.

The encapsulation film 136 can be disposed on at least some of the first semiconductor layer 131, the active layer 132, the second semiconductor layer 133, the anode 134, and the cathode 135. For example, the encapsulation film 136 can surround at least some of the first semiconductor layer 131, the active layer 132, the second semiconductor layer 133, the anode 134, and the cathode 135.

For example, the encapsulation film 136 can protect the first semiconductor layer 131, the active layer 132, and the second semiconductor layer 133. For example, the encapsulation film 136 can be disposed on the side surfaces of the first semiconductor layer 131, the active layer 132, and the second semiconductor layer 133.

For example, the encapsulation film 136 can be disposed on at least a portion of each of the anode 134 and the cathode 135, for example, on an edge portion (or one side) of the anode 134 and an edge portion (or one side) of the cathode 135. At least a portion of the anode 134 can be exposed from the encapsulation film 136, thereby allowing the anode 134 to be connected to the solder pattern SDP. For example, at least a portion of the cathode 135 can be exposed from the encapsulation film 136, thereby allowing the cathode 135 to be connected to the second electrode CE2. For example, the encapsulation film 136 can be formed of an insulating material such as silicon nitride (SiNₓ) or silicon oxide (SiOₓ), but the embodiments of the present disclosure are not limited thereto.

For another example, the encapsulation film 136 can have a structure in which a reflective material is dispersed in a resin layer, but the embodiments of the present disclosure are not limited thereto. For example, the encapsulation film 136 can be fabricated as a reflector with various structures, but the embodiments of the present disclosure are not limited thereto. Light emitted from the active layer 132 can be reflected upward by the encapsulation film 136, thereby enhancing light extraction efficiency. For example, the encapsulation film 136 can be a reflective layer, but the embodiments of the present disclosure are not limited thereto.

According to the present disclosure, the light-emitting element ED has been described as having a vertical structure, but the embodiments of the present disclosure are not limited thereto. For example, the light-emitting element ED can have a lateral structure or a flip chip structure.

Although the first light-emitting element 130 has been described, the second light-emitting element 140 and the third light-emitting element 150 can have substantially the same structure as the first light-emitting element 130. For example, the second light-emitting element 140 and the third light-emitting element 150 can have substantially the same structure as the first semiconductor layer 131, the active layer 132, the second semiconductor layer 133, the anode 134, the cathode 135, and the encapsulation film 136 of the first light-emitting element 130.

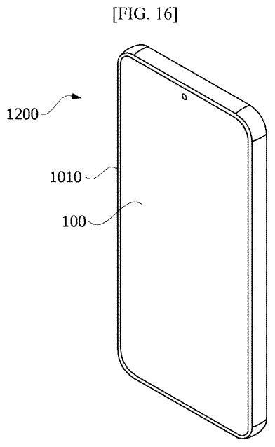

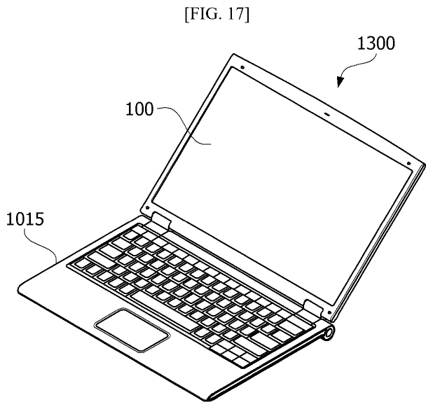

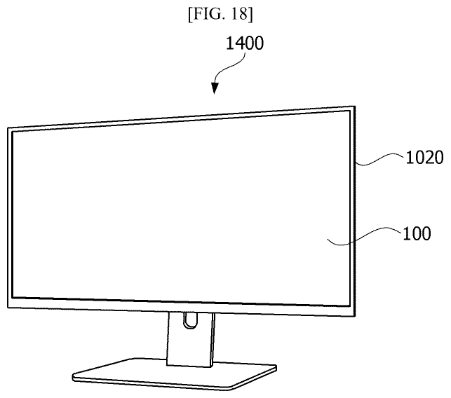

FIGS. 15 to 18 are views illustrating devices to which the display devices according to the embodiments of the present disclosure are applied.

Referring to FIGS. 15 to 18, a display device 1000 according to the embodiments of the present disclosure can be included in various devices or electronic devices. For example, the various electronic devices can include a wearable device 1100, a mobile device 1200, a laptop computer 1300, and a monitor or TV 1400, but the embodiments of the present disclosure are not limited thereto.

The wearable device 1100, the mobile device 1200, the laptop computer 1300, and the monitor or TV 1400 can include case parts 1005, 1010, 1015, and 1020, respectively, and can each include the display panel 100 and the display device 1000 according to the embodiments of the present disclosure described above.

For example, the display device according to the embodiment of the present disclosure can be applied to mobile devices, video phones, smart watches, watch phones, wearable devices, foldable devices, rollable devices, bendable devices, flexible devices, curved devices, sliding devices, variable devices, electronic organizers, e-books, portable multimedia players (PMPs), personal digital assistants (PDAs), MP3 players, mobile medical devices, desktop personal computers (PCs) s, laptop PCs, netbook computers, workstations, navigation devices, vehicle display devices, theater display devices, televisions, wallpaper devices, signage devices, gaming devices, laptop computers, monitors, cameras, camcorders, household appliances, and the like.

The display panel and the method of manufacturing the same according to one or more embodiments of the present disclosure can be described as follows.

A display panel according to the embodiments of the present disclosure includes a first light-emitting element disposed on a first bank, a second light-emitting element disposed on a second bank, and a third light-emitting element disposed on a third bank, wherein the first light-emitting element, the second light-emitting element, and the third light-emitting element can emit light of different wavelengths, and at least one of the first bank, the second bank, and the third bank can have a size different from a size of any of the other banks.

In the display panel according to the embodiments of the present disclosure, each of the first bank, the second bank, and the third bank can have a first length in a first direction, a second length in a second direction orthogonal to the first direction, and a thickness in a third direction, and the first length of the first bank can be greater than the first length of each of the second and third banks.

In the display panel according to the embodiments of the present disclosure, the second length of the first bank can be greater than the second length of each of the second and third banks.

In the display panel according to the embodiments of the present disclosure, the thicknesses of the first, second, and third banks in the third direction can be the same.

In the display panel according to the embodiments of the present disclosure, a first spacing between the first bank and the second bank in a first direction can be different from a second spacing between the second bank and the third bank in the first direction.

In the display panel according to the embodiments of the present disclosure, the first spacing can be greater than the second spacing.

In the display panel according to the embodiments of the present disclosure, the first light-emitting element, the second light-emitting element, and the third light-emitting element can include inorganic light-emitting elements.

In the display panel according to the embodiments of the present disclosure, a length of the first light-emitting element in a first direction can be different from a length of the second light-emitting element in the first direction, a length of the first light-emitting element in a second direction can be different from a length of the second light-emitting element in the second direction, the length of the first light-emitting element in the first direction can be different from a length of the third light-emitting element in the first direction, and the length of the first light-emitting element in the second direction can be different from a length of the third light-emitting element in the second direction.

In the display panel according to the embodiments of the present disclosure, the lengths of the first light-emitting element in the first direction and the second direction can be greater than the lengths of the second light-emitting element in the first direction and the second direction, and the lengths of the first light-emitting element in the first direction and the second direction can be greater than the lengths of the third light-emitting element in the first direction and the second direction.

In the display panel according to the embodiments of the present disclosure, a length of the second light-emitting element in a first direction can be the same as a length of the third light-emitting element in the first direction, and a length of the second light-emitting element in a second direction can be the same as a length of the third light-emitting element in the second direction.

In the display panel according to the embodiments of the present disclosure, a thickness of the first light-emitting element in a third direction can be different from a thickness of the second light-emitting element in the third direction, and the thickness of the first light-emitting element in the third direction can be different from a thickness of the third light-emitting element in the third direction.

In the display panel according to the embodiments of the present disclosure, each of the first, second, and third light-emitting elements can include a main light-emitting element and a redundancy light-emitting element configured to emit light at the same wavelength as the main light-emitting element.

In the display panel according to the embodiments of the present disclosure, the main light-emitting element and the redundancy light-emitting element can be disposed on the same bank.

A method of transferring light-emitting elements to a display panel according to an embodiment of the present disclosure includes picking up a plurality of light-emitting elements using a plurality of pickup heads disposed on a light-emitting element transfer apparatus, transporting the pickup heads to which the light-emitting elements are attached to a substrate, and separating the light-emitting elements from the pickup heads to transfer the light-emitting elements onto the substrate, wherein the substrate can include a first bank onto which a first light-emitting element is to be transferred, a second bank onto which a second light-emitting element is to be transferred, and a third bank onto which a third light-emitting element is to be transferred, wherein the first light-emitting element, the second light-emitting element, and the third light-emitting element can emit light of different wavelengths, and at least one of the first bank, the second bank, and the third bank can have a size different from a size of any of the other banks.

In the transfer method for a display panel according to the embodiment of the present disclosure, the separating of the light-emitting elements from the pickup heads to transfer the light-emitting elements onto the substrate can include attaching a plurality of first light-emitting elements that emit light in a first wavelength band to the pickup heads to simultaneously pick up the first light-emitting elements; transferring the first light-emitting elements onto the substrate by repeating, N times (where N is a positive integer greater than or equal to 2), an operation of separating some of the first light-emitting elements to be transferred this time from the corresponding pickup heads and transferring the some first light-emitting elements onto the substrate, moving the pickup heads, and separating others of the first light-emitting elements to be transferred this time from the corresponding pickup heads and transferring the other first light-emitting elements onto the substrate; attaching a plurality of second light-emitting elements that emit light in a second wavelength band to the pickup heads to simultaneously pick up the second light-emitting elements; transferring the second light-emitting elements onto the substrate by repeating, N times, an operation of separating some of the second light-emitting elements to be transferred this time from the corresponding pickup heads and transferring the some second light-emitting elements onto the substrate, moving the pickup heads, and separating others of the second light-emitting elements to be transferred this time from the corresponding pickup heads and transferring the other second light-emitting elements onto the substrate; attaching a plurality of third light-emitting elements that emit light in a third wavelength band to the pickup heads to simultaneously pick up the third light-emitting elements; and transferring the third light-emitting elements onto the substrate by repeating, N times, an operation of separating some of the third light-emitting elements to be transferred this time from the corresponding pickup heads and transferring the some third light-emitting elements onto the substrate, moving the pickup heads, and separating others of the third light-emitting elements to be transferred this time from the corresponding pickup heads and transferring the other third light-emitting elements onto the substrate.

In the transfer method for a display panel according to the embodiment of the present disclosure, a spacing between the plurality of pickup heads can be smaller than a spacing between the banks onto which the light-emitting elements are transferred.

In the transfer method for a display panel according to the embodiment of the present disclosure, the light-emitting element can be aligned and transferred using one of a plurality of conductive layers, which are disposed above a plurality of banks disposed on the substrate, as an alignment key MK.

In the transfer method for a display panel according to the embodiment of the present disclosure, the light-emitting element transfer apparatus can include a stamp on which the plurality of pickup heads are disposed, and elastic members configured to connect the stamp and the plurality of pickup heads.

In the transfer method for a display panel according to the embodiment of the present disclosure, the plurality of pickup heads can pick up the light-emitting elements using adhesive layers.

In the transfer method for a display panel according to the embodiment of the present disclosure, the stamp can apply a voltage to the plurality of pickup heads to pick up the light-emitting elements.

According to aspects of the present disclosure, when transferring light-emitting elements onto a panel of a display device, the proportion of light-emitting elements that are erroneously transferred can be reduced, thereby ensuring economic efficiency.

According to aspects of the present disclosure, the process of removing erroneously transferred light-emitting elements from a display panel during a light-emitting element transfer process can be omitted, thereby reducing the overall process time.

The effects of the present disclosure are not limited to the effects mentioned above, and other effects not mentioned can be clearly understood by those skilled in the art to which the technical idea of the present disclosure pertains from the following description.

While the embodiments of the present disclosure have been described in detail above with reference to the accompanying drawings, the present invention is not necessarily limited to these embodiments, and various changes and modifications can be made without departing from the technical spirit of the present invention.

Accordingly, the embodiments of the present disclosure disclosed herein are intended to illustrate and not to limit the technical ideas of the present invention, and the scope of the technical ideas of the present invention is not limited by these embodiments.

Accordingly, the above-described embodiments of the present disclosure should be understood to be an example and not limiting in any aspect.

The scope of the present invention should be construed by the appended claims, and all technical ideas within the scope of their equivalents should be construed as being included in the scope of the present invention.

What is claimed is:

1. A display panel comprising:
a first light-emitting element disposed on a first bank;
a second light-emitting element disposed on a second bank; and
a third light-emitting element disposed on a third bank,
wherein the first light-emitting element, the second light-emitting element, and the third light-emitting element are configured to emit light of different wavelengths, and
wherein each of at least one of the first bank, the second bank, and the third bank has a size different from a size of each of any of the other banks among the first, second and third banks.

2. The display panel of claim 1, wherein each of the first bank, the second bank, and the third bank has a first length in a first direction, a second length in a second direction orthogonal to the first direction, and a thickness in a third direction, and
wherein the first length of the first bank is greater than the first length of each of the second and third banks.

3. The display panel of claim 2, wherein the second length of the first bank is greater than the second length of each of the second and third banks.

4. The display panel of claim 2, wherein the thicknesses of the first, second, and third banks in the third direction are the same.

5. The display panel of claim 1, wherein a first spacing between the first bank and the second bank in a first direction is different from a second spacing between the second bank and the third bank in the first direction.

6. The display panel of claim 5, wherein the first spacing is greater than the second spacing.

7. The display panel of claim 1, wherein the first light-emitting element, the second light-emitting element, and the third light-emitting element include inorganic light-emitting elements.

8. The display panel of claim 7, wherein a length of the first light-emitting element in a first direction is different from a length of the second light-emitting element in the first direction,
wherein a length of the first light-emitting element in a second direction is different from a length of the second light-emitting element in the second direction,
wherein the length of the first light-emitting element in the first direction is different from a length of the third light-emitting element in the first direction, and
wherein the length of the first light-emitting element in the second direction is different from a length of the third light-emitting element in the second direction.

9. The display panel of claim 8, wherein the lengths of the first light-emitting element in the first direction and the second direction are respectively greater than the lengths of the second light-emitting element in the first direction and the second direction, and
wherein the lengths of the first light-emitting element in the first direction and the second direction are respectively greater than the lengths of the third light-emitting element in the first direction and the second direction.

10. The display panel of claim 7, wherein a length of the second light-emitting element in a first direction is the same as a length of the third light-emitting element in the first direction, and
wherein a length of the second light-emitting element in a second direction is the same as a length of the third light-emitting element in the second direction.

11. The display panel of claim 7, wherein a thickness of the first light-emitting element in a third direction is different from a thickness of the second light-emitting element in the third direction, and
wherein the thickness of the first light-emitting element in the third direction is different from a thickness of the third light-emitting element in the third direction.

12. The display panel of claim 1, wherein each of the first, second, and third light-emitting elements includes a main light-emitting element, and a redundancy light-emitting element configured to emit light at a same wavelength as the main light-emitting element.

13. The display panel of claim 12, wherein the main light-emitting element and the redundancy light-emitting element are disposed on a same bank.

14. The display panel of claim 1, further comprising an optical layer disposed on the first, second and third light-emitting elements and configured to evenly diffuse the light emitted from the first, second and third light-emitting elements.

15. A method of transferring light-emitting elements to a display panel, the method comprising:
picking up light-emitting elements using pickup heads disposed on a light-emitting element transfer apparatus;
transporting the pickup heads to which the light-emitting elements are attached to a substrate; and
separating the light-emitting elements from the pickup heads to transfer the light-emitting elements onto the substrate,
wherein the substrate includes:
a first bank onto which a first light-emitting element is to be transferred;
a second bank onto which a second light-emitting element is to be transferred; and
a third bank onto which a third light-emitting element is to be transferred,
wherein the first light-emitting element, the second light-emitting element, and the third light-emitting element are configured to emit light of different wavelengths, and
wherein each of at least one of the first bank, the second bank, and the third bank has a size different from a size of each of any of the other banks among the first, second and third banks.

16. The method of claim 15, wherein the separating of the light-emitting elements from the pickup heads to transfer the light-emitting elements onto the substrate includes:
attaching first light-emitting elements configured to emit light in a first wavelength band to the pickup heads to simultaneously pick up the first light-emitting elements;
transferring the first light-emitting elements onto the substrate by repeating, N times, an operation of separating some of the first light-emitting elements to be transferred this time from the corresponding pickup heads and transferring the some first light-emitting elements onto the substrate, moving the pickup heads, and separating others of the first light-emitting elements to be transferred this time from the corresponding pickup heads and transferring the other first light-emitting elements onto the substrate, where N is a positive integer greater than or equal to 2;
attaching second light-emitting elements configured to emit light in a second wavelength band to the pickup heads to simultaneously pick up the second light-emitting elements;
transferring the second light-emitting elements onto the substrate by repeating, N times, an operation of separating some of the second light-emitting elements to be transferred this time from the corresponding pickup heads and transferring the some second light-emitting elements onto the substrate, moving the pickup heads, and separating others of the second light-emitting elements to be transferred this time from the corresponding pickup heads and transferring the other second light-emitting elements onto the substrate;
attaching third light-emitting elements configured to emit light in a third wavelength band to the pickup heads to simultaneously pick up the third light-emitting elements; and
transferring the third light-emitting elements onto the substrate by repeating, N times, an operation of separating some of the third light-emitting elements to be transferred this time from the corresponding pickup heads and transferring the some third light-emitting elements onto the substrate, moving the pickup heads, and separating others of the third light-emitting elements to be transferred this time from the corresponding pickup heads and transferring the other third light-emitting elements onto the substrate.

17. The method of claim 15, wherein a spacing between the pickup heads is smaller than a spacing between the first, second and third banks onto which the light-emitting elements are transferred.

18. The method of claim 15, wherein one of the light-emitting elements is aligned and transferred using one of conductive layers, which are disposed on banks disposed on the substrate, as an alignment key.

19. The method of claim 15, wherein the light-emitting element transfer apparatus includes:
a stamp on which the pickup heads are disposed, and
elastic members configured to connect the stamp and the pickup heads.

20. The method of claim 15, wherein each of the first, second, and third light-emitting elements includes a main light-emitting element and a redundancy light-emitting element configured to emit light of a same wavelength, and
wherein the method further comprises performing a lighting test on the main light-emitting element and the redundancy light-emitting element in each of the first, second, and third light-emitting elements, to determine one of the main light-emitting element and the redundancy light-emitting element that is to be used.
